(19) United States
(12) Patent Application Publication
(10) Pub. No.: US 2026/0073088 A1
(43) Pub. Date: Mar. 12, 2026

(54) PARAMETER OPTIMIZATION METHOD

(71) Applicant: KABUSHIKI KAISHA TOSHIBA, Tokyo (JP)

(72) Inventors: Hiro GANGI, Marugame Kagawa (JP); Yasunori TAGUCHI, Kawasaki Kanagawa (JP); Tomoaki INOKUCHI, Yokohama Kanagawa (JP); Taichi FUKUDA, Yokohama Kanagawa (JP)

(73) Assignee: KABUSHIKI KAISHA TOSHIBA, Tokyo (JP)

(21) Appl. No.: 19/259,102

(22) Filed: Jul. 3, 2025

(30) Foreign Application Priority Data
Sep. 12, 2024 (JP) 2024-158630

(51) Int. Cl. G06F 30/17

(52) U.S. Cl. CPC G06F 30/17

(57) ABSTRACT

Plural neighboring design value sets are generated, from a representative design value set input to a simulator to acquire a representative characteristic value set. A first neighboring design value set is input from plural neighboring design value sets to acquire a neighboring characteristic value set, and a calculation score is calculated from neighboring characteristic values included in the neighboring characteristic value set. The magnitude relation between the calculation score and the discontinuation threshold is determined, and when the criterion is satisfied, the second neighboring design value set is input to the simulator. If the criterion is not satisfied, the value of the objective function is calculated from the characteristic values included in the neighboring characteristic value set. Finally, an acquisition function is calculated from the proxy model of the objective function by Bayesian estimation, and a new representative design value set is generated based on the acquisition function.

### CROSS-REFERENCE TO RELATED APPLICATION(S)

This application is based upon and claims the benefit of priority from Japanese Patent Application No. 2024-158630, filed Sep. 12, 2024, the entire contents of which are incorporated herein by reference.

### FIELD

Embodiments described herein relate generally to a parameter optimization method that is robust to parameter variations.

### BACKGROUND

Development of a technique that can support design of a device or the like is desired. When a device to be designed is manufactured, manufacturing variations may occur.

### BRIEF DESCRIPTION OF THE DRAWINGS

FIG. 1 is a block diagram showing a functional configuration of a parameter optimization method according to a first embodiment.

FIG. 2 is a schematic view illustrating a representative design set and a neighboring design set used in the parameter optimization method according to the embodiment.

FIG. 3 is a schematic diagram showing the structure of a calculation unit.

FIG. 4 is a schematic diagram showing the structure of a determination unit.

FIG. 5 is a flowchart showing a parameter optimization method according to the embodiment.

FIG. 6 is a schematic cross-sectional view illustrating a hardware configuration of the parameter optimization system.

FIG. 7 is a flowchart showing a parameter optimization method according to the first embodiment.

FIG. 8 is a schematic cross-sectional view illustrating the structure of a semiconductor element.

FIG. 9 is a table showing an example of design items.

FIG. 10 is a schematic view showing the correspondence between design items and semiconductor elements.

FIG. 11 is a table showing an example of characteristic items.

FIG. 12 is a schematic cross-sectional view illustrating the structure of another semiconductor element.

FIG. 13 is a graph showing the transition of the value of the objective function of the reference example and the proposed method.

FIG. 14A is a graph showing the transition of the number of times of discontinuation in the reference example.

FIG. 14B is a graph showing the transition of the number of times of discontinuation of the proposed method.

FIG. 15 is a flowchart showing a parameter optimization method according to the second embodiment.

FIG. 16 is a flowchart showing a parameter optimization method according to the third embodiment.

FIG. 17 is a flowchart showing a parameter optimization method according to the fourth embodiment.

FIG. 18 is a schematic view showing an example of a partial search space.

### DETAILED DESCRIPTION

In general, according to one embodiment, a parameter optimization method includes
generating a plurality of neighboring design value sets from a first representative design value set for a device,
acquiring from a simulator a first representative characteristic value set by inputting the first representative design value set to the simulator,
performing by the simulator a simulation related to a characteristic of the device,
acquiring a first neighboring characteristic value set output from the simulator in response to an input of a first neighboring design value set included in the plurality of neighboring design value sets,
calculating, in a calculation processor, a first calculation score calculated from the neighboring characteristic values included in the first neighboring characteristic value set,
determining, in the calculation processor, a magnitude relationship between the first calculation score and a discontinuation threshold,
inputting a second neighboring design value set included in the plurality of neighboring design value sets to the simulator if the first calculation score is greater than a discontinuation threshold,
calculating, in the calculation processor, a value of an objective function by inputting, to the objective function, a characteristic value included in the first representative characteristic value set and a characteristic value included in a neighboring characteristic value set output from the simulator in response to an input of one of neighboring design value sets included in the plurality of neighboring design value sets if the first calculation score is less than a discontinuation threshold,
calculating, in the calculation processor, an acquisition function by Bayes estimation from a proxy model of the objective function, the proxy model generated from a plurality of datasets stored in a storage,
generating a second representative design value set based on the acquisition function; and
when the second representative design value set satisfies a specified count, outputting the second representative design value set.

Hereinafter, embodiments for carrying out the invention will be described. In the specification and the drawings, the same reference numerals are given to the same elements as those described above, and detailed description thereof will be appropriately omitted.

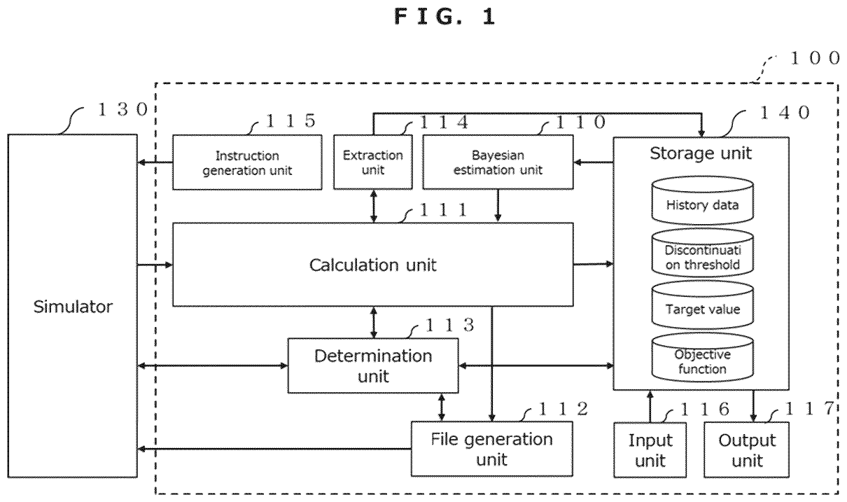

FIG. 1 is a block diagram showing a functional configuration of a parameter optimization method according to an embodiment.

The parameter optimization method according to the embodiment is used, for example, to search for design values of one or more design items related to a device. The design items are items related to design and can be freely set by the user. The parameter optimization system includes a parameter optimization apparatus 100 and a simulator 130. The parameter optimization apparatus 100 searches for a design value using the simulator 130. The parameter optimization method according to the embodiment is not necessarily limited to optimization of design parameters of a device. The present invention is also applicable to a case where design items can be defined by constructing a physical model, such as optimization of operation conditions of a semiconductor manufacturing apparatus.

The design object of the parameter optimization system is the design value of the design item. The design object includes, for example, design values related to a semiconductor device, a hard disk drive, a sensor device, an industrial robot, a gas component ratio, a plasma generation voltage, and the like.

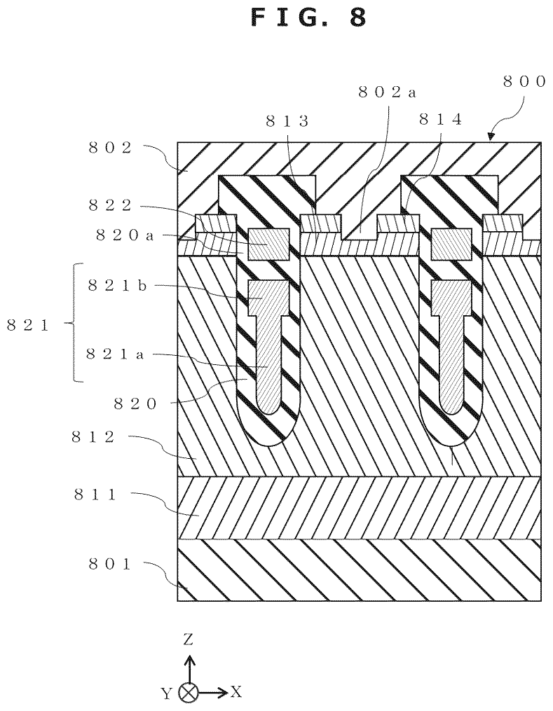

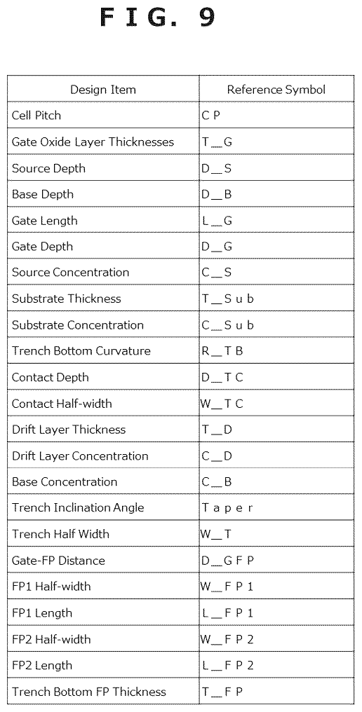

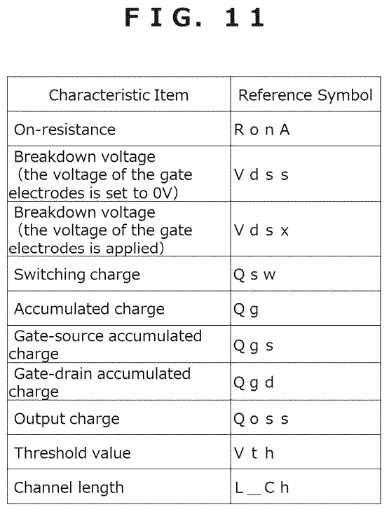

The configuration and operation of the parameter optimization system will be described below by taking a semiconductor element as an example of a design object. The semiconductor element includes, for example, a metal oxide semiconductor field effect transistor (MOSFET), an insulated gate bipolar transistor (IGBT), a diode, and the like. The semiconductor element illustrated is a MOSFET shown in FIG. 8, and has a plurality of design items shown in FIG. 9 and a plurality of characteristic items shown in FIG. 11. A set of design items required for designing an object device is referred to as a design item set X. A set of design values corresponding to the design items of the design item set X is referred to as a design value set x. The design item set X of the MOSFET includes, for example, items such as the impurity concentration of each semiconductor layer, the thickness of each semiconductor layer, and the dimensions of other elements. A value indicating a characteristic of an object device is a characteristic value, and an item thereof is a characteristic item. The characteristic items of the MOSFET include, for example, on-resistance, breakdown voltage, and switching charge. The configuration of the MOSFET to be designed will be described later.

Hereinafter, a specific design item or a specific design item group is represented by a capital alphabet, and a corresponding design value and a corresponding design value group are represented by a small alphabet. When a design value, a design value group, or a design value set in the i-th search cycle is referred to, (i) is added. Here, i is a natural number of 1 or more. The individual design items included in each design item group and the individual design values included in each design value group are denoted with a hyphen (-) and a number.

The simulator 130 simulates the characteristics of the device based on the input design value set x, and calculates a corresponding characteristic value set y.

The design items and design values input to the simulator 130 will be described below. The design item set X includes a design item group A, a design item group B, and a design item group C. The design item group includes one or more design items.

The arbitrary design value set x includes a design value group a corresponding to the design item group A, a design value group b corresponding to the design item group B, and a design value group c corresponding to the design item group C. Each design value group includes a plurality of design values corresponding to each of the plurality of design items included in the corresponding design item group.

The design item group A includes one or more design items to be searched. The design item to be searched for is a design item to be optimized in designing the device. The design item group A includes a design item A-1, a design item A-2, . . . , and a design item A-N1 (N1 is a natural number of 1 or more). The number of design items included in the design item group A is not limited, but is preferably 1 to 20 as a practical range. The design item group B includes one or more design items in which manufacturing variations are taken into consideration.

The design item group B includes a design item B-1, a design item B-2, . . . , and a design item B-N2 (N2 is a natural number of 1 or more). The design item group C indicates one or more design items obtained by excluding the design item group A and the design item group B from the design item set X.

The design item group C includes a design item C-1, a design item C-2, . . . , and a design item C-N3 (N3 is a natural number of 1 or more).

The design value set x includes a representative design value set x_center and a neighboring design value set x_risk. The representative design value set x_center is a design value set to be searched. The representative design value set x_center in the i-th search cycle is referred to as a representative design value set x_center(i). The representative design value set x_center(i) includes a design value group a(i), a representative design value group b_center, and a design value c. A new representative design value set x_center(i+1) is generated by changing the value of the design value group a based on the acquisition function. The representative design value group b_center of the representative design value set x_center (i) is changed to the neighboring design value group b_risk, thereby generating the neighboring design value set x_risk (i).

The neighboring design value set x_risk is a design value set in which the values of the design item group B are neighboring values of the representative design value group b_center of the representative design value set x_center to be searched. The neighboring design value set x_risk corresponds to a design value set assuming a case where manufacturing variation occurs in the design item group B in the device of the representative design value set x_center. The values of the design value group a are adjusted by inputting the neighboring design value set x_risk to the simulator.

The neighboring design value set x_risk in the i-th search cycle is referred to as a neighboring design value set x_risk(i). In the i-th search cycle, N4 neighboring design value sets x_risk(i) are generated. The plurality of neighboring design value sets x_risk(i) are extracted at equal intervals by normalizing the ends of the confidence interval of the representative design value set x_center(i) as circular points. When individual neighboring design value sets x_risk(i) are distinguished, they are respectively denoted by x_risk(i)[1], x_risk(i)[2], . . . , x_risk(i)[N4]. An arbitrary n-th neighboring design value set is denoted by x_risk(i)[n]. The neighboring design value set x_risk(i) in the i-th search cycle includes a design value group a (i), a neighboring design value group b_risk, and a design value c.

In the representative design value set x_center(i) and the neighboring design value set x_risk(i) of the i-th search cycle, the values corresponding to the design item A-1, the design item A-2, . . . , and the design item A-N1 are the design values a-1(i), a-2(i), . . . , and a-N1(i), respectively. In the i-th search cycle, the values of the design item group A of the representative design value set x_center(i) and the neighboring design value set x_risk(i) are the same.

The representative design value set x_center(i) of the i-th search cycle includes a design value group a(i), a representative design value group b_center, and a design value group c. In the representative design value set x_center(i) of the i-th search cycle, the values corresponding to the design item B-1, the design item B-2, . . . , and the design item B-N2 are a representative design value b-1_center, a representative design value b-2_center, . . . , and a representative design value b-N2 center, respectively.

The values of the design item group B of an arbitrary neighboring design value set x_risk(i) in the i-th search cycle are represented as a design value group b_risk(i). In an arbitrary neighboring design value set x_risk(i) in the i-th search cycle, values corresponding to the design item B-1, the design item B-2, . . . , and the design item B-N2 are respectively represented as a neighboring design value b-1_risk(i), a neighboring design value b-2_risk(i), . . . , and a neighboring design value b-N2 risk(i).

In the n-th neighboring design value set x_risk(i)[n] in the i-th search cycle, the values of the design item group B are represented as a neighboring design value group b_risk[n]. In the n-th neighboring design value set x_risk(i)[n] in the i-th search cycle, values corresponding to the design item B-1, the design item B-2, . . . , and the design item B-N2 are respectively denoted as a neighboring design value b-1 risk[n], a neighboring design value b-2_risk[n], . . . , and a neighboring design value b-N2_risk[n].

In the representative design value set x_center(i) and the neighboring design value set x_risk(i) of the i-th search cycle, the values corresponding to the design item C-1, the design item C-2, . . . , and the design item C-N3 are the design values c-1, c-2, . . . , and c-N3, respectively. The values of the design item group C of the representative design value set x_center(i) and the neighboring design value set x_risk(i) in the i-th search cycle are the same. The values of the design item group C of the representative design value set x_center(i) and the representative design value set x_center(i+i) are the same. Since the values of the design item group C are fixed values, they can be held in a text file.

When the representative design value set x_center(i) is input to the simulator, the representative characteristic value set y_center(i) is output, and when the neighboring design value set x_risk(i) is input to the simulator, the neighboring characteristic value set y_risk(i) is output.

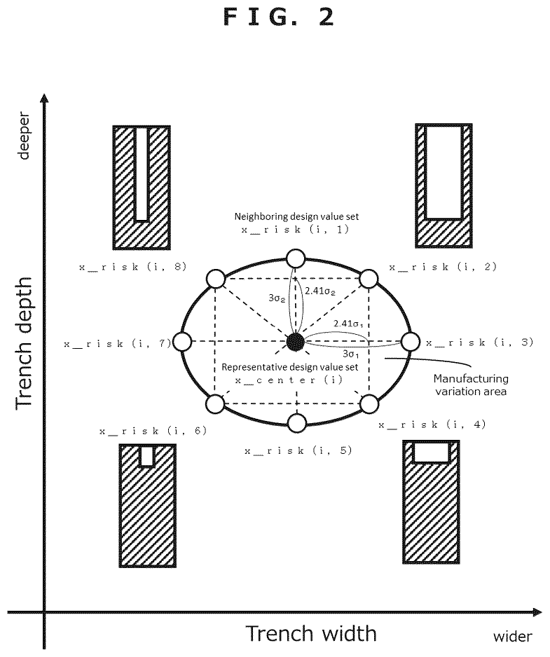

As shown in FIG. 2, there are N4 neighboring design value sets x_risk(i) for one representative design value set x_center(i). Each value included in the neighboring design value group b_risk included in the neighboring design value set x_risk(i) can be determined in consideration of the manufacturing variation of the value of each design item of the design item group B when the product is manufactured with the representative design value set x_center(i). The standard deviations of the manufacturing variations in the design items B-m (m is a natural number from 1 to N2) are represented by σₘ. An arbitrary neighboring design value b-m risk of the design item group B may be obtained by the following formula.

$$\begin{matrix}[ Formula 1 ] & \\ b - m\_risk = b - m\_center + α * {σ}_{m} & ( 1 )\end{matrix}$$

(α is a real number excluding zero)

The value a can be freely set according to the tolerance of manufacturing variation. A value of −7 or more and −2 or less, or a value of 2 or more and 7 or less, for example, ±3 may be used as α. The design values of the design item group B other than the design item B-m may be the same as those of the representative design value group b_center.

The standard deviation σₘ can be set to a value corresponding to the characteristics of a manufacturing apparatus used to actually manufacture an object product. A predetermined value that allows for manufacturing variations can be used as the standard deviation σₘ. For example, the standard deviation σₘ may be obtained by the following formula.

$$\begin{matrix}[ Formula 2 ] & \\ {σ}_{m} = β * b - 1 \_center & ( 2 )\end{matrix}$$

(β is a positive real number excluding zero)

The value β can be freely set according to the characteristics of the manufacturing apparatus. A value of 0.1% or more and 10% or less, for example, 2% may be used as B.

A method of selecting the neighboring design value when there are a plurality of design items will be described below. It is assumed that the variations of the design items B-1, B-2, . . . , B-N2 follow independent normal distributions. The user inputs standard deviations σ₁, σ₂, . . . , σ_{N2} of the variations of the design items. The user also inputs the percentage probability they want to consider for varying situations. Here, 99.7% corresponding to 3σ is taken as an example.

The product may be manufactured by the representative design value set x_center(i) by an actual manufacturing apparatus, and the dispersion may be examined by actual measurement. Alternatively, the standard deviation may be obtained by multiplying the value of each representative design value b_center by a constant. For example, 2%. This means that the standard deviation of each design value is shifted by 2% from the design value.

The neighboring design value is a design value for measuring how much the characteristics deteriorate due to the manufacturing variation. Therefore, it is necessary to be appropriately separated from the representative design value set x_center(i), and it is desirable that the respective neighboring design values are separated from each other. In order to satisfy this condition, for example, when the manufacturing variation is considered in the range of 3σ (99.7%), a 99.7% confidence interval is drawn with the representative design value x_center set (i) as the center, and the end of the confidence interval may be selected so that the neighboring design values standardized as circular points are arranged at equal intervals.

An embodiment of the neighboring design value set x_risk(i,k) (k=1, . . . , N4) will be described below. FIG. 2 shows an example in which the number of design items (design items B) in which the manufacturing variation of the device is considered is two. The vertical axis and the horizontal axis represent the respective design items. There are eight neighboring design values in total. These neighboring design values are not selected at once, but are selected in a case where the number of design items that vary at the same time is one, and in a case where the number of design items that vary at the same time is two, and so on. The specific procedure is as follows.

First, in FIG. 2, a case where one design item independently varies is considered. Attention is paid to a case where only the design item (trench width) on the horizontal axis varies. When the standard deviation of the variation in the trench width is σ₁, a point x_risk(i,3) having a variation of +3σ₁ in the horizontal axis direction and a point x_risk(i,7) having a variation of −3σ₁ are selected as the neighboring design values. Next, attention is paid to a case where only the design item (trench depth) of the vertical axis varies. When the standard deviation of the variation in the trench depth is σ₂, a point x_risk(i,1) having a variation of +3σ₂ in the vertical axis direction and a point x_risk(i,5) having a variation of −3σ₂ are selected as the neighboring design values.

Next, in FIG. 2, a case where two design items vary at the same time will be considered. Assuming that the respective design items vary according to independent normal distributions, the probability distribution of the variations is a two dimensional normal distribution, and the end of the 99.7% confidence interval is an ellipse expressed by the following formula.

$$\begin{matrix}[ Formula 3 ] & \\ {( {x}_{1} - {x\_center}_{1} )}^{2} / {σ}_{1}^{2} + {( {x}_{2} - {x\_center}_{2} )}^{2} / {σ}_{2}^{2} = {D}_{2}^{2} & ( 3 )\end{matrix}$$

Here, with respect to the coordinate vectors x and x_center, components in the horizontal axis direction are denoted by x₁ and x_center₁, and components in the vertical axis direction are denoted by x₂ and x_center₂. Here, D₂ is a quantity called a Mahalanobis distance. D₂ is obtained by calculation by inputting 99.7% to the probability density function of the Chi-square distribution with two degrees of freedom. The solid black circle shown in FIG. 2 is this ellipse. The remaining four neighboring design values are selected on the ellipse. The selection is made by selecting a point at which a diagonal line passing through the representative design value intersects with the ellipse. There are two diagonal lines, which are expressed by the following formula.

$$\begin{matrix}[ Formula 4 ] & \\ ( {X}_{1} - {X\_center}_{1} ) / {σ}_{1} + ( {x}_{2} - {x\_center}_{2} ) / {σ}_{2} = 0 & ( 4 )\end{matrix}$$

$$\begin{matrix}[ Formula 5 ] & \\ ( {X}_{1} - {X\_center}_{1} ) / {σ}_{1} - ( {x}_{2} - {x\_center}_{2} ) / {σ}_{2} = 0 & ( 5 )\end{matrix}$$

When these values are calculated, a point at which the variation on the horizontal axis is ±2.41σ₁ and the variation on the vertical axis is ±2.410₂ is the neighboring design value. By selecting the intersection points of these diagonal lines and ellipses, four neighboring design values x_risk(i,2), x_risk(i,4), x_risk(i,6), and x_risk(i,8) shown in FIG. 2 are determined.

When the number of design items B is two as in the embodiment of FIG. 2, the end of the confidence interval is an ellipse. On the other hand, when the number of design items B is three or more, the shape of the end of the confidence interval is a multidimensional ellipsoid. Even in the case of such a high dimension, the neighboring design value can be appropriately determined by expanding the method of FIG. 2. For example, when the number of design items B is Nb (Nb≥3), the neighboring design values are obtained by the following procedure.

First, consider a case where the number of design items that vary simultaneously is one, that is, a case where the design items vary independently. In this case, as the end of the 99.7% confidence interval, all points moved by +3σ and points moved by −3σ in the direction in which the respective design variables vary may be counted, as in the case where x_risk(i,k) (k=1, 3, 5, 7) is selected in FIG. 2. There are 2×Nb such points.

Next, a case where the number of design items that vary at the same time is two will be considered. Since the total number of design items that vary is Nb, there are _{Nb}C₂ combinations in which two of the design items vary simultaneously. First, attention is paid to one combination. When the combination of interest is referred to as the first design item and the second design item, the end of the 99.7% confidence interval at this time is a two dimensional ellipsoid represented by the following formula.

$$\begin{matrix}[ Formula 6 ] & \\ {( {x}_{1} - {x\_center}_{1} )}^{2} / {σ}_{1}^{2} + {( {x}_{2} - {x\_center}_{2} )}^{2} / {σ}_{2}^{2} = {D}_{2}^{2} & ( 3 )\end{matrix}$$

Here, with respect to the coordinate vectors x and x_center, components in the first direction are denoted by x₁ and x_center₁, and components in the second direction are denoted by x₂ and x_center₂. D₂ is a Mahalanobis distance, and can be obtained by inputting 99.7% to a probability density function of a Chi-square distribution with two degrees of freedom.

The neighboring design value is selected such that the first component and the second component vary at the same ratio on the ellipse. In selecting such points, a rectangle that is tangent to the ellipse may be considered. That is, lines are drawn from the center of the ellipse toward the respective apexes of the rectangle, and the points at which the lines and the ellipse intersect are set as the neighboring design values. The number of intersections is equal to the number of vertices of the rectangle, and is therefore four.

When this procedure is performed for all the combinations of _{Nb}C₂, all the neighboring design values in the case where the number of design variables that vary simultaneously is two are selected. The total number is 4×_{Nb}C₂.

Further, a case where the number of design items that vary at the same time is three is considered. The number of design items that vary is Nb, and there are _{Nb}C₃ combinations in which three of the design items vary simultaneously. First, attention is paid to one combination. When the combination of interest is referred to as a first design item, a second design item, and a third design item, the end of the 99.7% confidence interval at this time is an ellipsoid represented by the following formula.

$$\begin{matrix}[ Formula 7 ] & \\ {Σ}_{j} = {( {}_{1 , 2 , 3} {x}_{j} - {x\_center}_{j} )}^{2} / {σ}_{j}^{2} = {D}_{3}^{2} & ( 6 )\end{matrix}$$

Here, components of the coordinate vectors x and x_center in the j-th direction are denoted by xⱼ and x_centerⱼ, respectively (j=1,2,3). D₃ is the Mahalanobis distance, which can be obtained by inputting 99.7% to the probability density function of the Chi-square distribution with three degrees of freedom.

The neighboring design value is selected such that the first component, the second component, and the third component vary at the same ratio in the ellipsoid. When selecting such a point, a rectangular parallelepiped that is in contact with the ellipsoid may be considered. That is, lines are drawn from the center of the ellipsoid toward the respective apexes of the rectangular parallelepiped, and points at which the lines and the ellipsoid intersect may be set as the neighboring design values. The number of intersections is equal to the number of vertices of the rectangular parallelepiped, and is therefore eight.

When this procedure is performed for all the combinations of _{Nb}C₃, all the neighboring design values in the case where the number of design variables that vary simultaneously is three are selected. The total number of the capacitors is 8×_{Nb}C₃.

In this way, by increasing the number of design items that vary simultaneously to four, five, . . . , and counting up to Nb, and normalizing the design items as spherical points, it is possible to obtain appropriately dense and equally spaced neighboring design values.

When the number is four or more, the same applies to the case of three. For example, if the number of design items that vary simultaneously is L (4≤L≤Nb), the neighboring design value in this case can be obtained as follows. The number of design items that vary is Nb, and there are _{Nb}C_{L} combinations in which L design items simultaneously vary. First, attention is paid to one combination. When the combination of interest is referred to as a first design item, a second design item, . . . , and an L-th design item, the end of the 99.7% confidence interval at this time is an L-dimensional ellipsoid represented by the following formula.

$$\begin{matrix}[ Formula 8 ] & \\ {Σ}_{j} = {( {}_{1 , … , L} {x}_{j} - {x\_center}_{j} )}^{2} / {σ}_{j}^{2} = {D}_{L}^{2} & ( 7 )\end{matrix}$$

Here, components of the coordinate vectors x and x_center in the j-th direction are denoted by xⱼ and x_centerⱼ, respectively (j=1, 2, . . . , L). D_{L} is a Mahalanobis distance, and can be obtained by inputting 99.7% to a probability density function of a Chi-square distribution with a degree of freedom L.

The neighboring design value is selected from the L-dimensional ellipsoid in which each component is dispersed at the same ratio. When selecting such a point, it is preferable to consider an L-dimensional rectangular parallelepiped that is in contact with the L-dimensional ellipsoid. That is, lines are drawn from the center of the L-dimensional ellipsoid toward the respective vertices of the L-dimensional rectangular parallelepiped, and the points at which the lines and the L-dimensional ellipsoid intersect may be set as the neighboring design values. The number of intersections is equal to the number of vertices of the L-dimensional rectangular parallelepiped, and is therefore 2^{L}.

When this procedure is performed for all of the _{Nb}C^{L} combinations, all of the neighboring design values in the case where the number of design variables that vary simultaneously is L are selected. The total number of the capacitors is 2^{L}×_{Nb}C_{L}.

When the design items that vary simultaneously are counted in order from one to Nb, the number of neighboring design values is Σⱼ=_{1, . . . , Nb} 2^{j}×_{Nb}Cⱼ. If the number of the neighboring design values is enormous when the number of the neighboring design values is counted up to Nb, the counting may be stopped halfway, and a small number of neighboring design values may be used.

The characteristic items and the characteristic value sets output by the simulator 130 will be described below. A set of characteristic items output from the simulator 130 is referred to as a characteristic item set Y, and a corresponding set of characteristic values is referred to as a characteristic value set y. The characteristic item refers to an item output when the design item is input to the simulator 130. The simulator 130 outputs a representative characteristic value set y_center(i) and a neighboring characteristic value set y_risk(i)[n] in response to the input of the representative design value set x_center(i) and the neighboring design value set x_risk(i)[n]. The simulator 130 sends the output representative characteristic value set y_center(i) to the extraction unit 114. The simulator 130 also sends the output neighboring characteristic value set y_risk(i)[n] to the calculation unit 111.

As illustrated in FIG. 1, the parameter optimization apparatus 100 includes a Bayesian estimation unit 110, a calculation unit 111, a file generation unit 112, a determination unit 113, an extraction unit 114, an instruction generation unit 115, an input unit 116, an output unit 117, and a storage unit 140.

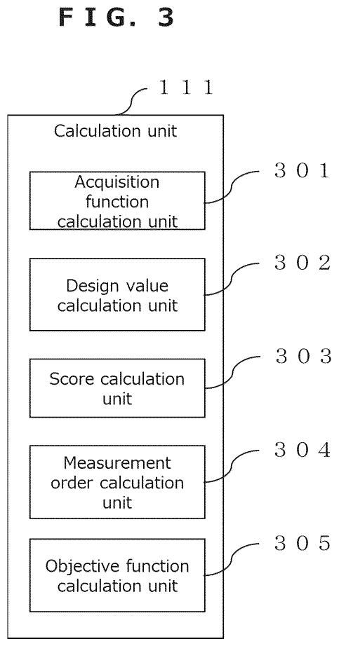

FIG. 3 shows a functional configuration of the calculation unit 111. As illustrated in FIG. 3, the calculation unit 111 includes an acquisition function calculation unit 301, a design value calculation unit 302, a score calculation unit 303, a measurement order calculation unit 304, and an objective function calculation unit 305.

The acquisition function calculation unit 301 and the design value calculation unit 302 will be described later. When the neighboring characteristic value set y_risk(i) is output from the simulator 130, the score calculation unit 303 calculates a calculation score. The calculation score is calculated by a specific characteristic value of a certain characteristic value group or a combination of specific characteristic values. Here, the higher the value of the calculation score, the more representative the characteristic value. The score calculation unit 303 transmits the calculation result of the calculation score to the determination unit 113, the extraction unit 114, and the storage unit 140.

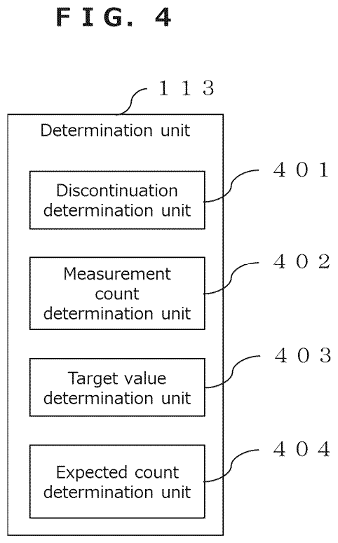

FIG. 4 shows a functional configuration of the determination unit 113. As shown in FIG. 4, the determination unit 113 includes a discontinuation determination unit 401, a measurement count determination unit 402, a target value determination unit 403, and an expected count determination unit 404.

The discontinuation determination unit 401 accesses the storage unit 140 and acquires the discontinuation threshold. The discontinuation determination unit 401 determines the magnitude relationship between the calculation score output from the score calculator 303 and the discontinuation threshold. The discontinuation determination unit 401 sends the determination result to the storage unit 140.

When the calculation score is equal to or larger than the discontinuation threshold, the measurement count determination unit 402 determines whether all of the representative design value set x_center(i) and the neighboring design value set x_risk(i) stored in the file generation unit 112 have been input to the simulator 130. The determination result is sent to the storage unit 140.

When the calculation score is less than the discontinuation threshold in the discontinuation determination unit 401, or when all of the representative design value set x_center(i) and the neighboring design value set x_risk(i) stored in the generation unit 112 are input to the simulator 130 in the measurement count determination unit 402, the extraction unit 114 extracts a characteristic value of a predetermined characteristic item from the representative characteristic value set y_center(i) when the representative characteristic value set y_center(i) and the neighboring characteristic value set y_risk(i) are output from the simulator 130. For example, the design value Ron-center. The extraction unit 114 extracts a characteristic value related to a predetermined characteristic item from the neighboring characteristic value set y_risk(i)[n]. For example, the characteristic value Vdss-worst has the lowest calculation score. The extraction unit 114 sends the extracted characteristic values to the calculation unit 111. The extraction unit 114 may extract two characteristic values from the neighboring characteristic value set y_risk(i).

When the measurement count determination unit 402 determines that at least one of the representative design value sets x_center(i) and the neighboring design value sets x_risk(i) stored in the file generation unit 112 have not been input to the simulator 130, the measurement count determination unit 402 sends the remaining representative design value sets x_center(i) and the neighboring design value sets x_risk(i) to the simulator 130.

The objective function calculation unit 305 accesses the storage unit 140 and acquires the objective function.

The objective function calculation unit 305 inputs the characteristic value extracted from the representative characteristic value set y_center(i) and the characteristic value having the lowest calculation score extracted from the neighboring characteristic value set y_risk(i)[n] to the objective function, and calculates the value of the objective function. The objective function is a function for calculating a calculation score from a characteristic value, and is set in advance by the user.

The objective function calculation unit 305 stores the calculated value of the objective function in the storage unit 140 in association with the representative characteristic value set y_center(i) and the neighboring characteristic value set y_risk(i) including the characteristic value input to the objective function and the representative design value set x_center(i) and the neighboring design value set x_risk(i) which are the basis of the characteristic value group.

The storage unit 140 stores the discontinuation threshold, the target value, the history data, the objective function, and the specified count. The discontinuation threshold is a value for comparing the magnitude relationship with the calculation score of the characteristic value. In order to reduce the simulation count or to terminate the simulation of an inappropriate design value as soon as possible, the discontinuation threshold may be gradually increased while searching. The historical data includes one or more data sets. Each data set includes a calculation score and a value of the objective function. The representative characteristic value set y_center(i) and the neighboring characteristic value set y_risk(i) including the characteristic values input to the objective function, and the representative design value set x_center(i) and the neighboring design value set x_risk(i) which are the basis of the characteristic value groups are associated with the values of the objective function.

The target value determination unit 403 determines the magnitude relationship between the value of the objective function calculated by the objective function calculation unit 305 and the target value. The target value determination unit 403 sends the determination result to the storage unit 140.

When the target value determination unit 403 determines that the value of the objective function exceeds the target value, the expected count determination unit 404 determines the magnitude relation between the number of times the representative design value set x_center(i) and the neighboring design value set x_risk (i) are calculated by the design value calculation unit 302 and the specified count. The expected count determination unit 404 sends the determination result to the storage unit 140.

When a new data set is stored in the storage unit 140 from the score calculation unit 303 and the objective function calculation unit 305, the Bayesian estimation unit 110 accesses the storage unit 140 and acquires history data obtained so far. The Bayesian estimation unit 110 estimates a proxy model of the objective function from the history data and sends the proxy model to the acquisition function calculation unit 301.

The acquisition function calculation unit 301 calculates an acquisition function from a proxy model of the objective function. The acquisition function calculation unit 301 sends the acquisition function to the design value calculation unit 302.

The design value calculation unit 302 calculates a new representative design value set x_center(i+1) and a new neighboring design value set x_risk(i+1) based on the acquisition function. The design value calculation unit 302 sends the calculated new representative design value set x_center(i+1) and the new neighboring design value set x_risk(i+1) to the file generation unit 112 and the storage unit 140. The design value calculation unit 302 sends the new neighboring design value set x_risk(i+1) to the score calculation unit 303. When a design value, a design value group, or a design value set in the (i+1)-th search cycle is referred to, (i+1) is added. Here, i is a natural number of 1 or more. In the cycle immediately before the (i+1)-th search cycle, data denoted by (i) is used.

When the new neighboring design value set x_risk(i+1) is stored from the design value calculation unit 302, the score calculation unit 303 calculates the prediction score of each design value of the new neighboring design value group b_risk(i+1).

The prediction score is a regression value of the neighboring characteristic values or a combination of regression values of the neighboring characteristic values.

According to an embodiment, each prediction score is calculated from the new set of neighboring design values x_risk(i+1). The order of malignancy is determined based on the magnitude relationship of the prediction scores, the new neighboring design value set x_risk(i+1) is rearranged in the order of malignancy of the prediction scores, and a part of the new neighboring design value set x_risk(i+1) is input to the simulator in the order of malignancy of the prediction scores. The “order of malignancy” of the score means that the values of the score predicted or calculated from the neighboring design value set x_risk(i) are arranged in the order of the worst.

The measurement order calculation unit 304 determines the order of inputting the new neighboring design value set x_risk(i+1) to the simulator 130 based on the prediction score of the new neighboring design value group b_risk(i+1) calculated by the score calculation unit 303, and sends information on the simulation order to the file generation unit 112.

The file generation unit 112 generates a file to be input to the simulator 130. The file includes data of the new representative design set x_center(i), the new neighboring design value set x_risk(i+1), and the new neighboring design value b_risk(i+1) in the simulation order. For example, the number of design values calculated by the design value calculation unit 302 is the same as the number of design values included in the representative design value set x_center(i) and the neighboring design value set x_risk (i+1). In this case, the design value calculation unit 302 generates a new representative design value set x_center(i+1) and a new neighboring design value set x_risk(i+1). The number of new design values calculated by the design value calculation unit 302 may be smaller than the number of design values included in the representative design value set x_center(i) and the neighboring design value set x_risk(i). When the number of new design values to be calculated is smaller than the number of design values included in the representative design value set x_center(i) and the neighboring design value set x_risk(i), the file generating unit 112 adds the design value that is lacking as appropriate. In this case, the file generation unit 112 generates a new representative design value set x_center(i+1) and a new neighboring design value set x_risk(i+1). The file generation unit 112 inputs the new representative design value set x_center(i+1) and the new neighboring design value set x_risk(i+1) to the simulator 130.

The instruction generation unit 115 generates an execution instruction for causing the simulator 130 to execute simulation. The instruction generation unit 115 sends an execution command to the simulator 130 at a predetermined timing.

The simulator 130 executes simulation using the representative design value set x_center(i+1) or the neighboring design value set x_risk(i+1) input from the file generation unit 112. The simulator 130 outputs the new representative characteristic value set y_center(i+1) and the new neighboring characteristic value set y_risk(i+1) obtained as a result of the simulation to the extraction unit 114.

The input unit 116 is used by a user to input data to the parameter optimization system. The user can save data such as the discontinuation threshold, the target value, the objective function, the specified count, and the initial search condition necessary for the processing of the parameter optimization system in the storage unit 140 using the input unit 116.

When the target value determining unit 403 determines that the value of the objective function is smaller than the target value, or when the expected count determination unit 404 determines that the number of times the representative design value set x_center(i) and the neighboring design value set x_risk(i) are calculated exceeds the specified count, the output unit 117 outputs data indicating at least one selected from the group consisting of the representative design value set x_center(i), the neighboring design value set x_risk(i), the representative characteristic value set y_center(i), the neighboring characteristic value set y_risk(i), and the calculation score to the user. For example, the output unit 117 displays the number of repetitions of a process set including input of the representative design value group x_center(i) and the neighboring design value group x_risk(i), calculation of a prediction score, acquisition of the representative characteristic value group y_center(i) and the neighboring design value group y_risk(i), calculation of a calculation score, and generation of a new representative design value group x_center(i+1) and a new neighboring design value group x_risk(i+1), and the display of a new representative characteristic value group y_center(i+1), and a new neighboring characteristic value group y_risk(i+1). The output unit 117 may output the best design value set z_center of the device as data. Hereinafter, the processing set is also referred to as a “trial”. The output unit 117 may display a structural diagram of the device that reflects the best design value set z_center after the trial is repeatedly executed.

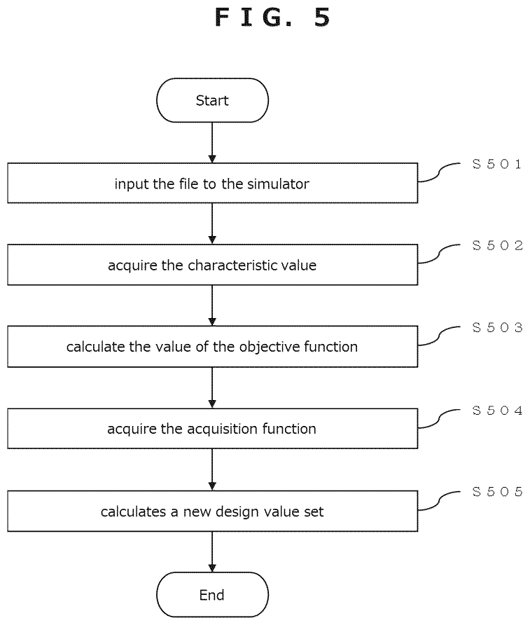

FIG. 5 is a flowchart showing a parameter optimization method according to the embodiment. In the parameter optimization method shown in FIG. 5, the file generation unit 112 generates a file to be input to the simulator 130 based on the calculated representative design value set x_center(i) and the plurality of neighboring design value sets x_risk(i), and inputs the file to the simulator 130. (Step S501).

The extraction unit 114 acquires a characteristic value related to a predetermined characteristic item from the representative characteristic value set y_center(i) output from the simulator 130. The extraction unit 114 acquires a characteristic value having the worst calculation score from the neighboring characteristic value set y_risk(i) (step S502).

The objective function calculation unit 305 calculates the value of the objective function by inputting the characteristic value of the predetermined characteristic item in the representative characteristic value set y_center(i) and the characteristic value having the worst calculation score in the neighboring characteristic value set y_risk(i) to the objective function (step S503).

The Bayesian estimation unit 110 generates a proxy model of the objective function from the history data including the combination of the calculation score and the value of the objective function, and sends the proxy model to the acquired function calculation unit 301. The acquisition function calculation unit 301 acquires the acquisition function based on the proxy model of the objective function, and sends the acquisition function to the design value calculation unit 302 (step S504).

The design value calculation unit 302 acquires a new representative design value set x_center(i+1) based on the acquisition function, and sends the new representative design value set x_center(i+1) to the design value calculation unit 302. The design value calculation unit 302 calculates a new design value set based on the acquisition function. The new calculated design value set includes a new representative design value set x_center (i+1) and a new neighboring design value set x_risk(i+1). (Step S505).

The trial including steps S501 to S505 is repeated to search for the design value of the device.

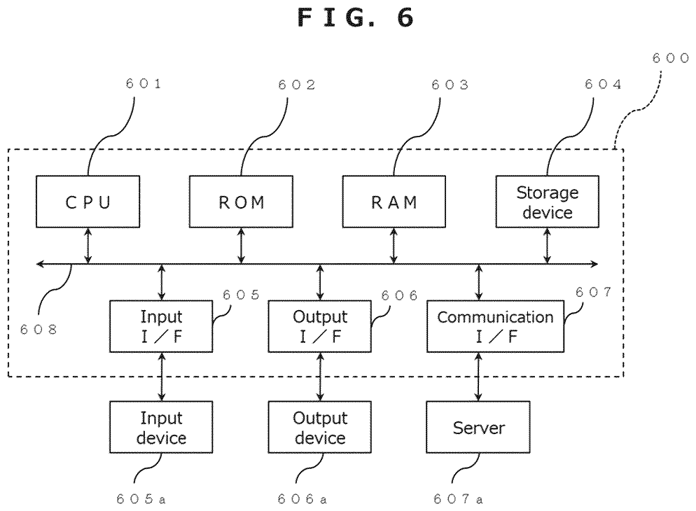

FIG. 6 is a schematic diagram illustrating a hardware configuration of the parameter optimization system. The parameter optimization system according to the embodiment can be realized by the hardware configuration of the parameter optimization system illustrated in FIG. 6. The processing apparatus 600 illustrated in FIG. 6 includes a CPU 601, a ROM 602, a RAM 603, a storage device 604, an input interface 605, an output interface 606, and a communication interface 607.

The ROM 602 stores a program for controlling the operation of the computer. The ROM 602 stores a program necessary for causing a computer to realize the above-described processes. The RAM 603 functions as a memory area where a program stored in the ROM 602 is loaded.

The CPU 601 includes processing circuitry. The CPU 601 executes a program stored in at least one of the RAM 603 and the storage device 604 using the ROM 602 as a work memory. During the execution of the program, the CPU 601 controls each component via the system bus 608 and executes various processes.

The storage device 604 stores data necessary for executing the program and data obtained by executing the program.

The input interface (I/F) 605 connects the processing apparatus 600 and the input device 605a. The input I/F 605 is, for example, a serial bus interface such as a universal serial bus (USB). The CPU 601 can read various kinds of data from the input device 605a via the I/F 605.

The outputting interface (I/F) 606 connects the processing apparatus 600 and the output device 606a. The output I/F 606 is, for example, a video output interface such as a digital visual interface (DVI) or a high definition multimedia interface (HDMI(registered trademark)). The CPU 601 transmits data to the output device 606a via the output I/F 606. The output device 606a outputs the date.

The communication interface (I/F) 607 connects the server 607a outside the processing apparatus 600 and the processing apparatus 600. The communication I/F 607 is, for example, a network card such as a LAN card. The CPU 601 can read various kinds of data from the server 607a via the communication I/F 607.

The storage device 604 includes one or more selected from a hard disk drive (HDD) and a solid state drive (SSD). The input device 605a includes one or more selected from a mouse, a keyboard, a microphone (voice input device), and a touch pad. The output device 606a includes one or more selected from a monitor, a printer, a speaker, and a projector. A device having both functions of the input device 605a and the output device 606a, such as a touch panel, may be used.

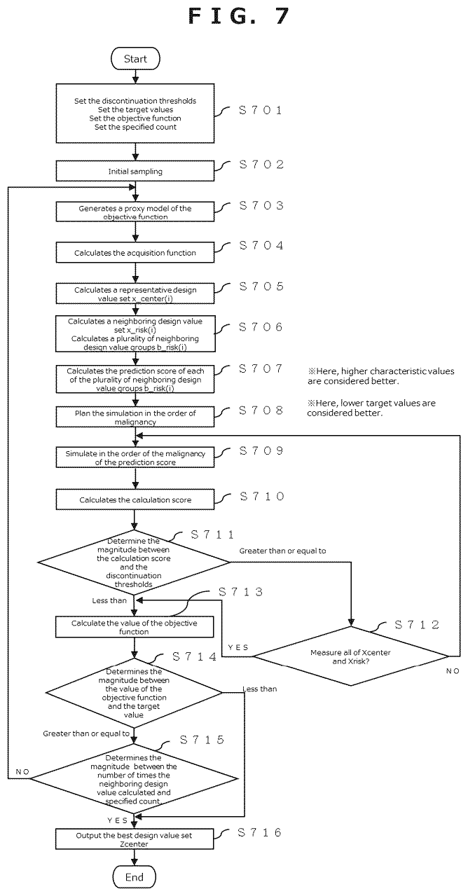

Hereinafter, the parameter optimization method according to the embodiment will be described with reference to a specific example. FIG. 7 is a flowchart showing a parameter optimization method according to the embodiment. In the parameter optimizing method shown in FIG. 7, the user sets the discontinuation thresholds, the target values, the objective function, and the specified count (step S701). Next, initial sampling is performed (step S702). In the initial sampling, the design value calculation unit 302 randomly sets the representative setting value set x_center(i) and the neighboring design value set x_risk(i), and the file generation unit 112 inputs the representative setting value set x_center(i) and the neighboring design value set x_risk(i) to the simulator 130.

The extraction unit 114 acquires a characteristic value related to a predetermined characteristic item of the representative characteristic value set y_center(i) output from the simulator 130 and a characteristic value having the worst calculation score of the neighboring characteristic value set y_risk(i).

The objective function calculation unit 305 calculates the value of the objective function by inputting the characteristic value of the predetermined characteristic item of the representative characteristic value set y_center(i) and the characteristic value of the worst calculation score of the neighboring characteristic value set y_risk(i) to the objective function. In the initial sampling, a trial including inputting of a representative design value set x_center(i) and a neighboring design value set x_risk(i), acquisition of a representative characteristic value set y_center(i) and a neighboring characteristic value set y_risk(i), calculation of a value of an objective function, and generation of a new representative design value set x_center(i+1) and a new neighboring design value set x_risk(i+1) is repeated. For example, the initial sampling is repeated 10 to 30 times. By repeating the initial sampling, the representative set of setting values x_center, the set of neighboring design values x_risk, the representative set of characteristic values y_center(i), the set of neighboring characteristic values y_risk(i), and the data set of the values of the objective function are repeatedly stored in the storage unit 140.

The Bayesian estimation unit 110 generates a proxy model of the objective function from the plurality of datasets stored in the storage unit 140, and sends the proxy model to the acquisition function calculation unit 301 (step S703).

The acquisition function calculation unit 301 calculates the acquisition function based on the proxy model of the objective function and sends the acquisition function to the design value calculation unit 302 (step S704).

The design value calculation unit 302 calculates a representative design value set x_center(i) based on the acquisition function (step S705). The design value calculation unit 302 calculates a neighboring design value set x_risk(i) based on the acquisition function and calculates a plurality of neighboring design value groups b_risk(i) based on the neighboring design value set x_risk(i) (step S706).

When the plurality of neighboring design value groups b_risk(i) are acquired, the score calculation unit 303 calculates the prediction score of each of the plurality of neighboring design value groups b_risk(i). (step S707).

The measurement order calculation unit 304 determines the order of simulation so that the plurality of neighboring design value groups b_risk(i) are input to the simulator 130 in order of worst prediction score. (Step S708).

The file generation unit 112 acquires a file for inputting the representative design value set x_center(i) calculated by the design value calculation unit 302 and the plurality of neighboring design value sets x_risk(i) arranged in order of worst prediction score by the measurement order calculation unit 304 to the simulator 130. The simulator 130 inputs the representative design value set x_center(i) and a plurality of neighboring design value sets x_risk(i) arranged in the order of worse prediction score (step S709). A representative characteristic value set y_center(i) is acquired by inputting the representative design value set x_center(i), and a neighboring characteristic value set y_risk(i) is acquired by inputting the neighboring design value set x_risk(i).

The score calculation unit 303 calculates the calculation score of the neighboring characteristic value set y_risk(i) output from the simulator 130 (step S710).

The discontinuation determination unit 401 determines the magnitude relationship between the calculation score of the neighboring characteristic value set y_risk(i) and the discontinuation thresholds (step S711).

If the calculation score is equal to or greater than the discontinuation thresholds, it is determined whether there is a representative design value set x_center(i) or a plurality of neighboring design value sets x_risk(i) that have not been input to the simulator (step S712). If there is the first representative design value set x_center(i) or the plurality of neighboring design value sets x_risk(i) that have not been input to the simulator, the remaining representative design value set x_center(i) or the plurality of neighboring design value sets x_risk(i) are input to the simulator (step S709), and the calculation score of the neighboring characteristic value group b_risk included in the neighboring characteristic value set y_risk(i) is calculated (step S710). The magnitude relationship between the calculation score and the discontinuation thresholds is determined again (step S711).

If the calculation score is less than the discontinuation thresholds, or if all the representative design value set x_center(i) and the neighboring design value set x_risk(i) are input to the simulator, the characteristic value of the predetermined characteristic item in the representative characteristic value set y_center(i) and the characteristic value of the neighboring characteristic value set y_risk i) having the worst calculation score are input to the objective function to calculate the value of the objective function (step S713). A magnitude relation between the value of the objective function and a target value is determined.

The target value determination unit 403 determines the magnitude relationship between the value of the objective function and the target value (step S714). When the value of the objective function is less than the target value, the best design value set z_center(i) is output from the history data, and the search is discontinued before all the representative design value sets x_center(i) and the neighboring design value sets x_risk(i) are input to the simulator.

When the value of the objective function exceeds the target value, the expected count determination unit 404 determines the magnitude relationship of the number of times the neighboring design value set x_risk(i) are calculated by the design value calculation unit 302 and a specified count. (Step S715).

When the value of the objective function is equal to or larger than the target value, it is determined whether the number of calculation of the neighboring design value set x_risk(i) has reached a specified count. When the value of the objective function is smaller than the target value, or when the number of calculations of the neighboring design value set reaches the specified count, the best design value set z_center(i) is output (step S716).

When the number of times the representative design value set x_center(i) and the neighboring design value set x_risk(i) are calculated in the design value calculation unit 302 is less than the specified count, step S703 is executed again. When the count of predictions of the representative design value set x_center(i) satisfies the specified count, the output unit 117 outputs the best design value set z_center. (Step S716).

The trial of steps S703 to S715 is repeated until the end condition is satisfied. As an example of the end condition, the representative characteristic value set y_center(i) or the neighboring characteristic value set y_risk(i) is below the discontinuation thresholds in step S711, all the representative design value sets x_center(i) and the neighboring design value sets x_risk(i) are input to the simulators 130 in step S712, the value of the objective function exceeds the target value in step S714, or the number of times the representative design value set x_center(i) and the neighboring design value sets x_risk(i) are calculated in step S715 satisfies a specified count.

The repeated trial includes: generating a proxy model of the objective function in step S703; calculating the acquisition function in step 704; calculating the representative design value set x_center(i) in step S705; calculating the neighboring design value set x_risk(i) and the neighboring design value group b_risk(i) in step S706; calculating the prediction score of the neighboring design value group b_risk(i) in step S707; planning the simulation order based on the prediction scores of the neighboring design value set x_risk(i) in step S708; inputting the representative design value set x_center(i) and the neighboring design value set x_risk(i) into the simulator in step S709; calculating the calculation scores of the neighboring characteristic value group y_risk(I,N) in step S710; determining the magnitude relationship between the calculation score and the discontinuation threshold in step S711; determining whether all the representative design value set x_center(i) and the neighboring design value set x_risk(i) have been input to the simulator 130 in step S712; calculating the objective function value in step S713; determining the magnitude relationship between the objective function value and the target value in step S714; and determining the magnitude relationship between the number of times the representative design value set x_center(i) and the neighboring design value set x_risk(i) have been calculated and the specified count in step S715. By repeating the trial, a preferable best design value set z_center regarding the design of the apparatus is searched.

As an example of an apparatus to be designed, a structure of a semiconductor element will be described. FIG. 8 is a schematic cross-sectional view illustrating the structure of the semiconductor element. The parameter optimization system according to the embodiment searches for design values related to the structure of the semiconductor element 800 illustrated in FIG. 8. The semiconductor element 800 is a MOSFET.

The semiconductor element 800 includes a first electrode 801, a second electrode 802, an n⁺-type semiconductor layer 811, an n⁻-type semiconductor layer 812, a p-type semiconductor layer 813, an n⁺-type semiconductor layer 814, an insulating layer 820, a field plate electrode (hereinafter, referred to as an FP electrode) 821, and a gate electrode 822. The p-type and n-type of each semiconductor layer may be reversed.

The first electrode 801 and the second electrode 802 are spaced apart from each other. A direction from the first electrode 801 toward the second electrode 802 is defined as a Z direction. The n⁺-type semiconductor layer 811 is provided between the first electrode 801 and the second electrode 802. The n⁺-type semiconductor layer 811 is electrically connected to the first electrode 801. The n⁻-type semiconductor layer 812 is provided between the n⁺-type semiconductor layer 811 and the second electrode 802. The n-type impurity concentration in the n⁻-type semiconductor layer 812 is lower than the n-type impurity concentration in the n⁺-type semiconductor layer 811. The p-type semiconductor layer 813 is provided between the n⁻-type semiconductor layer 812 and the second electrode 802. The n⁺-type semiconductor layer 814 is provided between the p-type semiconductor layer 813 and the second electrode 802.

The insulating layer 820 is provided between the n⁺-type semiconductor layer 811 and the second electrode 802 in the Z-direction. The insulating layer 820 is arranged with a portion of the n⁻-type semiconductor layer 812, the p-type semiconductor layer 813, and a portion of the n⁺-type semiconductor layer 814 in the X-direction perpendicular to the Z-direction. A part of the insulating layer 820 is provided around the FP electrode 821. The direction from a portion of the n⁻-type semiconductor layer 812 to the FP electrode 821 is aligned with the X-direction. The gate electrode 822 is provided between the FP electrode 821 and the second electrode 802 in the Z direction. Another part of the insulating layer 820 is provided around the gate electrode 822. The direction from the gate electrode 822 to the p-type semiconductor layer 813 and the n⁺-type semiconductor layer 814 is aligned with the X-direction. The second electrode 802 is electrically connected to the p-type semiconductor layer 813, the n⁺-type semiconductor layer 814, and the FP electrode 821, and is electrically separated from the gate electrode 822.

In the semiconductor element 800, the FP electrodes 821 include first portions 821a and second portions 821b. The second portion 821b is provided between the first portion 821a and the gate electrodes 822. The widths (the lengths in the X direction) of the second portions 821b are wider than the widths of the first portions 821a. The gate electrode 822 is separated from the FP electrode 821 and is electrically isolated from the FP electrode 821. The second electrodes 802 include contact portions 802a. The contact portion 802a protrudes toward the p-type semiconductor layer 813.

In a state where a positive voltage is applied to the first electrode 801 with respect to the second electrode 802, a voltage equal to or higher than a threshold value is applied to the gate electrode 822. Thus, a channel (inversion layer) is formed in the p-type semiconductor layer 813, and the semiconductor element 800 is turned on. Electrons flow through the channel from the second electrode 802 to the first electrode 801. When the voltage applied to the gate electrode 822 becomes lower than a threshold value, the channel in the p-type semiconductor layer 813 disappears, and the semiconductor element 800 is turned off.

When the semiconductor element 800 is switched to the off state, the positive voltage applied to the first electrode 801 with respect to the second electrode 802 increases. At this time, a depletion layer spreads from the interface between the insulating layer 820 and the n⁻-type semiconductor layer 812 toward the n⁻-type semiconductor layer 812. The breakdown voltage of the semiconductor element 800 can be increased by the expansion of the depletion layer. Alternatively, the n-type impurity concentration in the n⁻-type semiconductor layer 812 can be increased and the on-resistance of the semiconductor element 800 can be reduced while maintaining the breakdown voltage of the semiconductor element 800.

The objective function outputs a value of the objective function in response to input of a part of the representative characteristic value set y_center(i) and a part of the neighboring characteristic value group y_risk(i, N). As an example, the first function f(x) is expressed by the following Equation 8. The representative characteristic value set y_center(i) (a part of the first characteristic value) of the on-resistance RonA and the neighboring characteristic value group y_risk(i, N) (a part of the second characteristic value) of the breakdown voltage BVdss are input to the first function f(x). Here, the on-resistance RonA is obtained by dividing a resistance value between an input terminal and an output terminal of a current when the semiconductor element is operated by an element area. The breakdown voltage BVdss indicates a breakdown voltage value between the input terminal and the output terminal of the current when the semiconductor element flows a specified leakage current. The ramp function ReLU outputs a numerical value as it is when the value is 0 or more, and outputs 0 when the value is less than 0. As an example, the objective function f is expressed by the following equation.

$$\begin{matrix}[ Formula 9 ] & \\ f = {RonA}^{center} / 30 + 10 ReLU ( 100 - {BVdss}^{worst} ) & ( 8 )\end{matrix}$$

The values “1/30” and “10” are values appropriately set by the user. “100” is the target value of BVdss^{worst}. By inputting RonA^{center} and BVdss^{worst} output from the simulator 130 to Equation 8, an objective function for the representative characteristic value set y_center(i) and the neighboring characteristic value set y_risk(i) is obtained. Here, the lower the value of the objective function, the more representative the design value. To prevent the divergence of the value of the objective function, the upper limit of the value is set to 10.

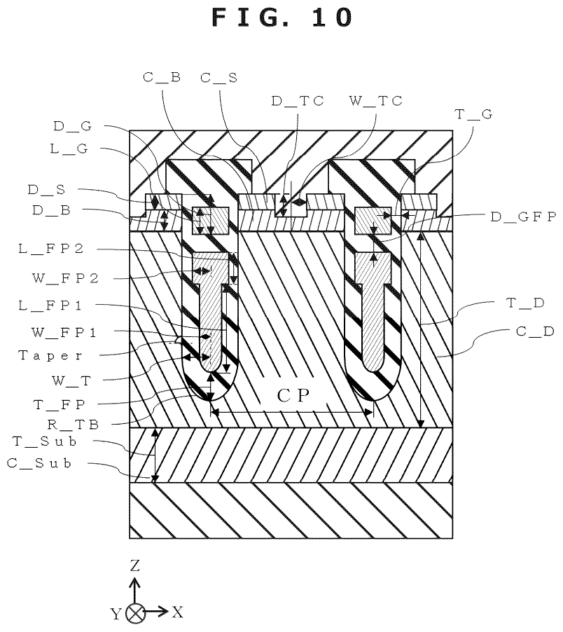

FIG. 9 is a table illustrating design items. FIG. 10 is a schematic diagram showing the correspondence between design items and semiconductor elements. The cell pitch in the table of FIG. 9 corresponds to the pitch CP (shown in FIG. 10) of the gate electrodes 822 in the X direction. The gate oxide layer thicknesses correspond to the thicknesses T G of the gate insulating layers 820a in the X direction. The source depth corresponds to the depth D_S in the Z direction of the n⁺-type semiconductor layer 814. The base depth corresponds to a depth D B in the Z direction from the boundary between the p-type semiconductor layer 813 and the n⁺-type semiconductor layer 814 to the boundary between the p-type semiconductor layer 813 and the n⁻-type semiconductor layer 812. The gate length corresponds to the length L_G of the gate electrode 822 in the Z direction. The gate depth corresponds to a depth D G in the Z-direction from the upper surface of the n⁺-type semiconductor layer 814 to the lower end of the gate electrode 822. The source concentration corresponds to the n-type impurity concentration C S in the n⁺-type semiconductor layer 814. The substrate thickness corresponds to the thickness T Sub of the n⁺-type semiconductor layer 811 in the Z-direction. The substrate concentration corresponds to the n-type impurity concentration C Sub in the n⁺-type semiconductor layer 811. The trench bottom curvature corresponds to the curvature R_TB at the lower end of the insulating layer 820. The contact depth corresponds to a depth D_TC in the Z-direction from the upper surface of the n⁺-type semiconductor layer 814 to the lower end of the contact portion 802a. The contact half-width corresponds to half the width W_TC of the contact portion 802a. The drift layer thickness corresponds to the thickness T D in the Z direction of the n⁻-type semiconductor layer 812. The drift layer concentration corresponds to the n-type impurity concentration C D in the n⁻-type semiconductor layer 812. The base concentration corresponds to the p-type impurity concentration C B in the p-type semiconductor layer 813. The trench inclination angle corresponds to an angle Taper between the side surface of the insulating layer 820 and the X direction. The trench half width corresponds to half the width W T of the insulating layer 820. The gate-FP distance corresponds to the distance D_GFP in the Z direction between the FP electrode 821 and the gate electrode 822. The FP1 half-width corresponds to half the width W_FP1 of the first portion 821a. The FP1 length corresponds to the length L_FP1 of the first portion 821a in the Z direction. The FP2 half-width corresponds to half the width W_FP2 of the second portion 821b. The FP2 length corresponds to the length L_FP2 of the second portion 821b in the Z direction. The trench bottom FP thickness corresponds to the thickness T_FP in the Z-direction of the lower end of the insulating layer 820.

FIG. 11 is a table illustrating characteristic items. The characteristic value group is output from the simulator by inputting one of the representative design value group and the neighboring design value group. The characteristic value group includes at least one characteristic value selected from the on-resistance, the breakdown voltage when the gate voltage is 0 [V], the breakdown voltage when the gate voltage is applied, the switching charge, the gate accumulated charge, the gate-source accumulated charge, the gate-drain accumulated charge, the output charge, the threshold voltage, and the channel length.

In the table of FIG. 11, the on-resistance RonA is an on-resistance per unit area when a voltage larger than a threshold value is applied to the gate electrode 822 and the semiconductor element 800 is turned on. The breakdown voltage Vdss is the breakdown voltage of the semiconductor element 800 when the voltage of the gate electrodes 822 with respect to the second electrodes 802 is set to 0V. The breakdown voltage Vdsx is the breakdown voltage of the semiconductor element 800 when the voltage of the gate electrodes 822 with respect to the second electrodes 802 is set to −20V. The switching charge Qsw is the total amount of charge accumulated in the gate electrode 822 when the gate voltage is equal to or higher than the threshold Vth and equal to or lower than the Mirror voltage in the switching state of the semiconductor element 800. The gate accumulated charge Qg is the amount of charge accumulated in the gate electrode 822 when the semiconductor element 800 is in the ON state. The gate-source accumulated charge Qgs is a part of the amount of charge accumulated between the gate electrode 822 and the second electrode 802 (source electrode) when the semiconductor element 800 is in the ON state. The gate-drain accumulated charge Qgd is a part of the amount of charge accumulated between the gate electrode 822 and the first electrode 801 when the semiconductor element 800 is in the ON state. The output charge Qoss is a part of the charge amount accumulated in the drain electrode (first electrode 801) when the semiconductor element 800 is in the off state. The threshold value Vth is a voltage applied to the gate electrode 822, which is necessary for forming a channel (inversion layer) in the p-type semiconductor layer 813. The channel length L_Ch is a length along the Z-direction from the boundary between the p-type semiconductor layer 813 and the n⁺-type semiconductor layer 814 to the boundary between the p-type semiconductor layer 813 and the n⁻-type semiconductor layer 812.

In the example of FIG. 9, there are 23 design items. The parameter optimization method according to the embodiment can be applied to these 23 design items. In the example of FIG. 11, there are ten characteristic items. Some of the characteristic items are extracted from these characteristic items, and the magnitude relationship between the calculation score and the discontinuation threshold is determined. Design items that provide better scores are searched for the extracted characteristic items. For example, the some characteristic items include an on-resistance and a breakdown voltage.

For example, a total of 1000 trials are performed for the design item shown in FIG. 9 using Equation (8) as the first function. By this search, it is possible to search for a design value that exhibits characteristics equivalent to those of the design value found by the skilled person. By executing the trial a larger number of times, it is possible to search for a design value that exhibits a characteristic superior to that of the skilled person.

As described above, the characteristics of the semiconductor element vary due to the influence of various design items. For example, in the characteristics of a semiconductor element, the on-resistance and the breakdown voltage are generally considered important. The on-resistance is affected by the concentration of each semiconductor layer, the thickness of each semiconductor layer, and the like. In particular, the impurity concentration in the n⁻-type semiconductor layer 812 (drift layer concentration) affects the on-resistance. The higher the impurity concentration in the n⁻-type semiconductor layer 812 is, the more the on-resistance is reduced. On the other hand, the breakdown voltage is improved as the impurity concentration in the n⁻-type semiconductor layer 812 is lower. In some of the design items, the on-resistance and the breakdown voltage have a trade-off relationship.

When the improvement of the characteristic value is intended, the design items may affect each other. For example, when the cell pitch is narrowed, the n⁻-type semiconductor layer 812 between the insulating layers 820 is easily depleted. Therefore, the breakdown voltage can be improved. Alternatively, the impurity concentration in the n⁻-type semiconductor layer 812 is increased in accordance with the n⁻-type semiconductor layer 812 between the insulating layers 820 being easily depleted, and thereby, the on-resistance can be reduced while maintaining the breakdown voltage. That is, the design value of the cell pitch can affect the impurity concentration in the n⁻-type semiconductor layer 812.

It takes a great deal of labor even for a skilled person to appropriately set a plurality of design items that affect both the on-resistance and the breakdown voltage while paying attention to the on-resistance and the breakdown voltage obtained from the simulator 130. According to the embodiment, it is possible to search for preferable design values for both the on-resistance and the breakdown voltage without requiring detailed examination by a person.

In this example, the design values of the plurality of design items shown in FIG. 9 are searched. It is also possible to search for some of the design values of the plurality of design items shown in FIG. 9 and set the other design items to fixed values. The impurity concentration in the n⁻-type semiconductor layer 812 has a large influence on the on-resistance and the breakdown voltage. Therefore, the impurity concentration in the n⁻-type semiconductor layer 812 is preferably a search target.

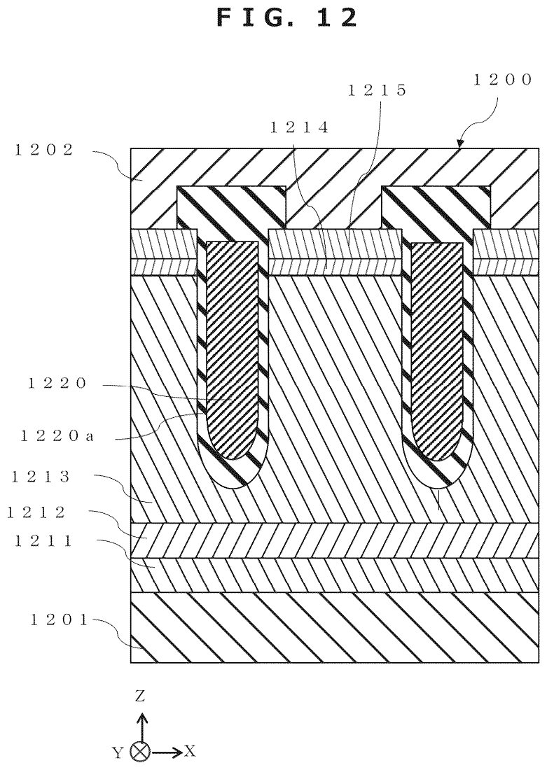

FIG. 12 is a schematic cross-sectional view illustrating the structure of another semiconductor element. The design value related to the structure of the semiconductor element 1200 illustrated in FIG. 12 may be searched by the parameter optimization system according to the embodiment. The semiconductor element 1200 is an IGBT.

The semiconductor element 1200 includes a first electrode 1201, a second electrode 1202, a p⁺-type semiconductor layer 1211, an n-type semiconductor layer 1212, an n⁻-type semiconductor layer 1213, a p-type semiconductor layer 1214, an n⁺-type semiconductor layer 1215, and a gate electrode 1220. The p-type and n-type of each semiconductor layer may be reversed.

The first electrode 1201 and the second electrode 1202 are spaced apart from each other. A direction from the first electrode 1201 toward the second electrode 1202 is defined as a Z direction. The p⁺-type semiconductor layer 1211 is provided between the first electrode 1201 and the second electrode 1202. The p⁺-type semiconductor layer 1211 is electrically connected to the first electrode 1201. The n-type semiconductor layer 1212 is provided between the p⁺-type semiconductor layer 1211 and the second electrode 1202. The n⁻-type semiconductor layer 1213 is provided between the n-type semiconductor layer 1212 and the second electrode 1202. The n-type impurity concentration in the n⁻-type semiconductor layer 1213 is lower than the n-type impurity concentration in the n-type semiconductor layer 1212. The p-type semiconductor layer 1214 is provided between the n⁻-type semiconductor layer 1213 and the second electrode 1202. The n⁺-type semiconductor layer 1215 is provided between the p-type semiconductor layer 1214 and the second electrode 1202.

The gate electrode 1220 is provided between the n-type semiconductor layer 1212 and the second electrode 1202 in the Z-direction. The direction from a portion of the n⁻-type semiconductor layer 1213, the p-type semiconductor layer 1214, and a portion of the n⁺-type semiconductor layer 1215 toward the gate electrode 1220 is aligned with the X-direction. A gate insulating layer 1220a is provided between the n⁻-type semiconductor layer 1213 and the gate electrodes 1220, between the p-type semiconductor layer 1214 and the gate electrodes 1220, and between the n⁺-type semiconductor layer 1215 and the gate electrodes 1220. The second electrode 1202 is electrically connected to the p-type semiconductor layer 1214 and the n⁺-type semiconductor layer 1215, and is electrically separated from the gate electrode 1220.

In a state where a positive voltage is applied to the first electrode 1201 with respect to the second electrode 1202, a voltage equal to or higher than a threshold value is applied to the gate electrode 1220. Thereby, a channel (inversion layer) is formed in the p-type semiconductor layer 1214. The electrons flow from the second electrode 1202 to the n⁻-type semiconductor layer 1213 through the channel. The holes flow from the first electrode 1201 to the n⁻-type semiconductor layer 1213 through the p⁺-type semiconductor layer 1211. Conductivity modulation occurs in the n⁻-type semiconductor layer 1213, and the electrical resistance of the n⁻-type semiconductor layer 1213 decreases. Thus, the semiconductor element 1200 is turned on. When the voltage applied to the gate electrode 1220 becomes lower than a threshold value, the channel in the p-type semiconductor layer 1214 disappears, and the semiconductor element 1200 is turned off.

The parameter optimization system according to the embodiment can search for the impurity concentration in each semiconductor layer, the thickness of each semiconductor layer, and the dimensions of other elements in the semiconductor element 1200 illustrated in FIG. 12, as in the semiconductor element 800. For example, the n-type impurity concentration in the n⁻-type semiconductor layer 1213 (drift layer concentration), the thicknesses of the n⁻-type semiconductor layer 1213 in the Z-direction (drift layer thickness), the pitches of the gate electrodes 1220 in the X-direction (cell pitch), the thicknesses of the gate insulating layers 1220a in the X-direction (gate oxide layer thicknesses), the depths of the n⁺-type layer 1215 in the Z-direction (source depth), the lengths of the p-type layer 1214 in the Z-direction (channel length), the lengths of the gate electrodes 1220 in the Z-direction (gate length), the depths of the n⁺-type layer 1215 from the upper surface to the lower ends of the gate electrodes 1220 (gate depth), the n-type impurity concentration in the n⁺-type layer 1215 (source concentration), the curvatures of the gate insulating layers 1220a at the lower ends (trench bottom curvature), the angles between the side surfaces of the gate insulating layers 1220a and the X-direction (trench inclination angle), and the widths of the gate insulating layers 1220a (trench half width), and the like can be searched.

Advantages of the embodiment will be described. For example, the design values of the semiconductor element are determined by a person by trial and error using a simulator. However, the semiconductor element includes many design items, and a burden on a person is large. Further, the characteristics of the semiconductor element, particularly, the on-resistance and the breakdown voltage vary due to the influence of various design items. Therefore, specialized knowledge and experience are required to evaluate the characteristic value for the input design value and determine the new design value. The evaluation of the characteristic value with respect to the design value varies depending on the person.

According to the embodiment, the input of the design value group to the simulator 130, the acquisition of the characteristic value group from the simulator 130, the evaluation, and the generation of the new design value group are automatically repeated. Therefore, the burden on the person can be reduced. Without requiring professional knowledge and experience, it is possible to suppress the variation in the evaluation of characteristic values.

According to the embodiment, the new design value group is generated based on the acquisition function by Bayesian estimation. When the Bayesian estimation is applied to the design of a semiconductor element including a large number of design values, a long time is required for the initial search as compared with the response surface method or the design by a human. However, the inventors have found that Bayesian estimation is particularly suitable for designing semiconductor elements. Bayesian estimation consequently enables the design value of a semiconductor element to be set to a more desirable value in a shorter time.

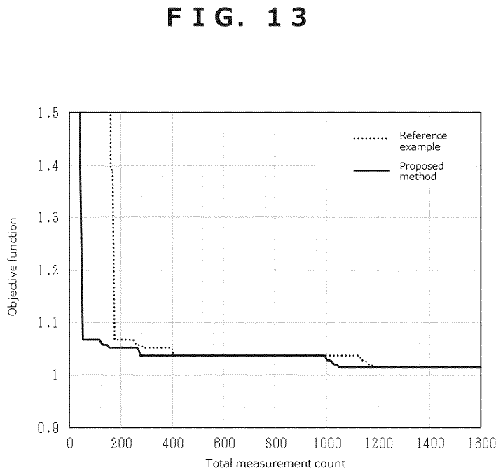

FIG. 13 is a diagram comparing the transition of the objective function between the reference example and the proposed method. The reference example refers to a technique in which a process of setting a neighboring design value and calculating a value of an objective function is added to the technique of Japanese Patent No. 7443224 which is a prior application. The horizontal axis represents the number of times the representative design value set x_center(i) or the neighboring design value set x_risk(i) is input to the simulator 130, and the vertical axis represents the value of the objective function. In the flowchart of the first embodiment in FIG. 7, the simulation in the “order of malignancy” of steps S707, S708, and S709, and S710, S711, and S712 are different from those of the reference example. Compared to the reference example, the proposed method can calculate a smaller value of the objective function with a smaller number of simulations. That is, a good design value can be output with a small number of simulations.

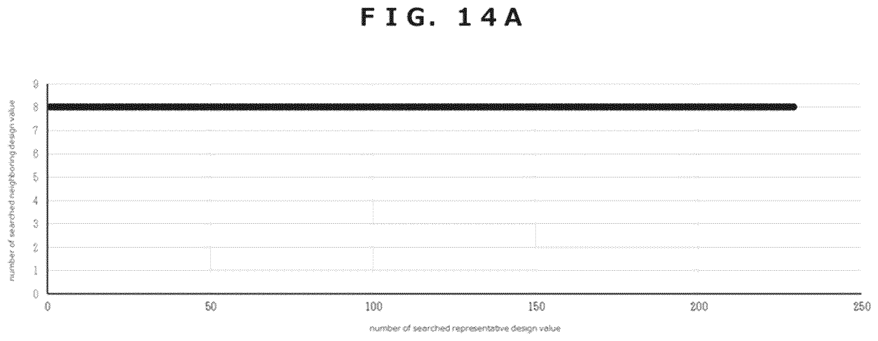

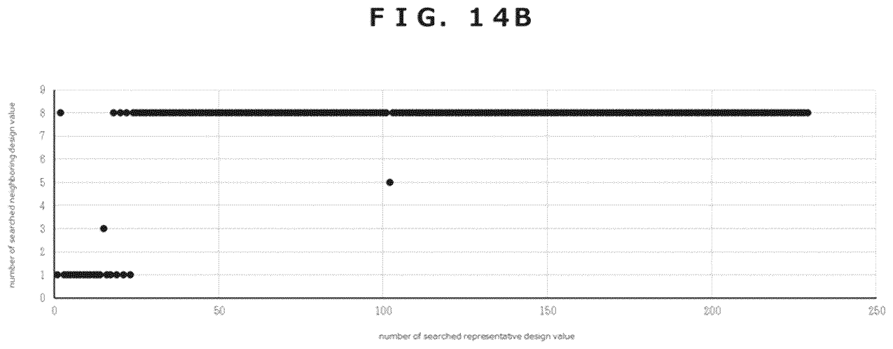

FIG. 14 is a diagram comparing the number of times of discontinuation between the reference example and the proposed method. The horizontal axis represents the number of times the representative design value set x_center(i) is calculated, and the vertical axis represents the number of neighboring design value sets x_risk(i) input to the simulator 130. In the reference example, all of the eight neighboring design value sets are input to the simulator 130 for all of the searched representative design value sets, and the simulation is performed. In contrast, in the proposed method, the search is discontinued by inputting one, three, or five neighboring design value sets to the simulator 130. In the proposed method, it is not necessary to input all of the eight neighboring design value sets to the simulator 130, and thus the simulation end condition can be satisfied more quickly than in the reference example.

### Second Embodiment

According to the second embodiment, the representative characteristic value set y_center(i) output from the simulator is acquired by inputting the representative design value set x_center(i), and the neighboring characteristic value set y_risk(i) output from the simulator is acquired by inputting one of the plurality of neighboring design value sets x_risk (i). A calculation score of the neighboring characteristic value b_risk included in the neighboring characteristic value set y_risk(i) is calculated, a magnitude relation between the calculation score and a discontinuation threshold is determined, and when the calculation score is equal to or larger than the discontinuation threshold, a new prediction score is calculated from the plurality of neighboring design value sets x_risk(i). It is determined whether or not the order of inputting the plurality of neighboring design value sets x_risk(i) rearranged in the order of the malignancy of the prediction score to the simulator is changed, and when the order of inputting is changed, a part of the neighboring design value sets x_risk(i) is input to the simulator in the order of the malignancy of the new prediction score. When the input order is not changed, it is determined whether there is a representative design value set x_center(i) or a plurality of neighboring design value sets x_risk(i) that have not been input to the simulator.

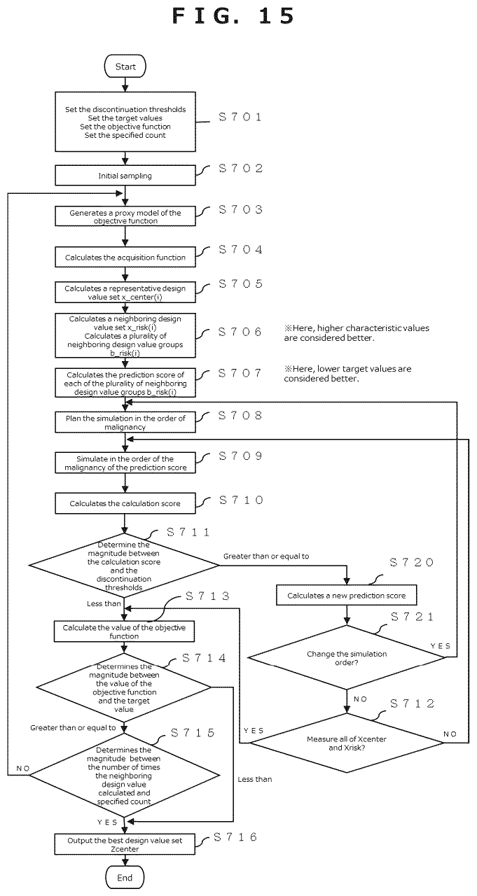

FIG. 15 is a flowchart showing a parameter optimization method according to the second embodiment of the present invention. In the parameter optimization method shown in FIG. 7, the order of the neighboring design value sets x_risk(i) arranged in the order of the malignancy of the prediction score is not changed until the last neighboring design value set x_risk(i) is input to the simulator 130. In the parameter optimization method according to the second embodiment shown in FIG. 15, before the last neighboring design value set x_risk(i) is input to the simulator 130, a new prediction score is calculated from the calculated calculation score, and the order of inputting the neighboring design value set x_risk(i) to the simulator 130 can be changed.

In the parameter optimizing method shown in FIG. 15, steps S701 to S711 are executed in the same manner as in the parameter optimizing method shown in FIG. 7. The second embodiment is different from the first embodiment in that steps S720 and S721 are added.

The discontinuation determination unit 401 determines the magnitude relationship between the calculation score of the neighboring characteristic value set y_risk(i) and the discontinuation thresholds (step S711). After the calculation score is determined to be equal to or larger than the discontinuation thresholds in step S711, learning is performed with the calculation score added each time the score calculation unit 303 calculates the calculation score, thereby creating a new regression model of the neighboring design value group b_risk(i). The score calculation unit 303 calculates a new prediction score from the same design value set by using the regression model (step S720). The measurement calculation unit 304 determines whether or not to change the simulation order (step S721). The measurement order calculation unit 304 can change the order of inputting the neighboring design value sets x_risk(i) to the simulator 130 based on the new prediction score before all the neighboring design value sets x_risk(i) are input to the simulator 130.

When the simulation order is changed in step S721, the neighboring design value sets x_risk(i) are planned to be input to the simulators 130 again in the order of the malignancy of the prediction score (step S708). If the simulation order is not changed in step S721, it is determined whether all the representative design value sets x_center(i) and the neighboring characteristic value sets x_risk (i) have been input to the simulators 130 (step S712).

After it is determined in step S711 that the calculation score is less than the discontinuation thresholds, steps S713 to S716 are executed as in the parameter optimizing method illustrated in FIG. 7.

According to the second embodiment, a new prediction score can be calculated in the middle of the search for the representative design value, and the simulation order can be changed in the middle of the search. For example, if it is determined in step S711 that the calculation score is larger than the termination value, a new prediction score is calculated and the simulation order is changed, thereby it can increase the possibility of obtaining more preferable characteristic values.

### Third Embodiment

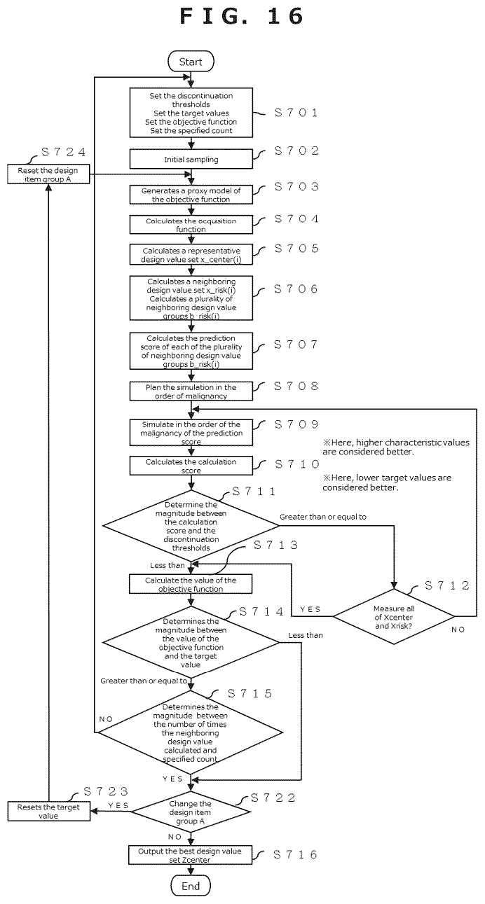

FIG. 16 is a flowchart showing a parameter optimization method according to the third embodiment of the present invention. In the parameter optimization method shown in FIG. 7, once the design item group A is set, it is not changed until the best design value set z_center(i) is output. In the parameter optimization method according to the third embodiment shown in FIG. 16, the design item group A can be changed before the best design value set z_center(i) is output.

In the parameter optimizing method shown in FIG. 16, steps S701 to S715 are executed in the same manner as in the parameter optimizing method shown in FIG. 7. The third embodiment is different from the first embodiment in that steps S722 to S724 are added.

When the value of the objective function exceeds the target value, the expected count determination unit 404 determines the magnitude relation between the number of times the representative design value set x_center and the neighboring design value set x_risk are calculated by the design value calculation unit 302 and the specified count. (Step S715). After the expected count determination unit 404 determines that the number of times of calculation of the neighboring design value is equal to or larger than the specified count in step S715, it is determined whether or not the design item group A is changed (step S722). When it is determined in step S722 that the design item group A is to be changed, the input unit 116 resets the target value (step S723). The reset target value is stored in the storage unit 140. Further, the design item group A is set again (step S724). If it is determined in step S722 that the design item group A is not to be changed, the outputting unit 117 outputs the best design value set z_center(i), and the simulation is terminated (step S716).

According to the third embodiment, the design item group A can be changed in the middle of the search for the representative design value. For example, when it is determined in step S715 that the number of calculations of the neighboring design value is larger than the specified count and it is determined that the number of searches using the design item group A set first is sufficient, it is determined in step S722 whether or not the design item group A is changed. Compared to the first embodiment, it can increase the possibility of obtaining more preferable characteristic values.

### Fourth Embodiment

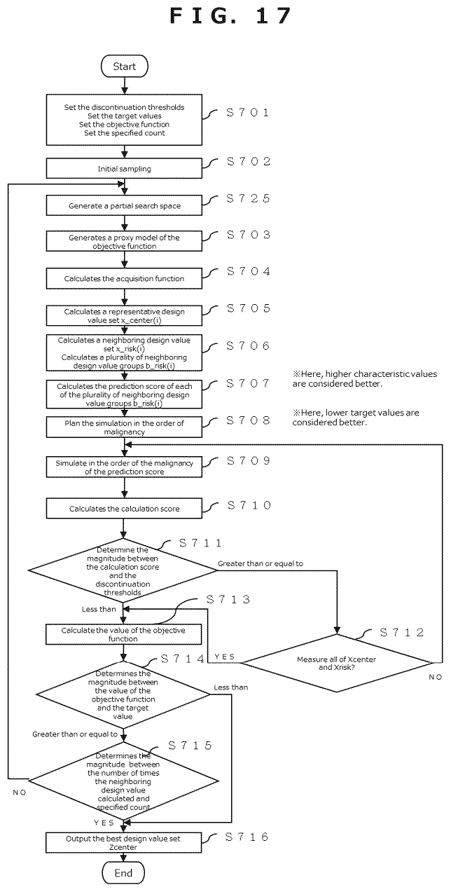

FIG. 17 is a flowchart showing a parameter optimization method according to the fourth embodiment of the present invention. In the parameter optimization method shown in FIG. 7, all of the set design item group A are targets of parameter optimization. In the parameter optimization method according to the fourth embodiment shown in FIG. 17, a part of the set design item group A can be optimized by performing the low-dimensional search. In another search, another design item group in the design item group A can be extracted and searched (optimized).

In the parameter optimizing method shown in FIG. 17, steps S701 and S702 are executed in the same manner as in the parameter optimizing method shown in FIG. 7. The fourth embodiment is different from the first embodiment in that a step S725 is added.

Initial sampling is performed (step S702). After the initial sampling is performed, a partial search space having a second number of dimensions smaller than a first number of dimensions is generated from a search space having the first number of dimensions (step S725). The Bayesian estimation unit 110 generates a proxy model of the objective function from the plurality of datasets stored in the storage unit 140 and sends the proxy model to the acquisition function calculation unit 301 (step S703).

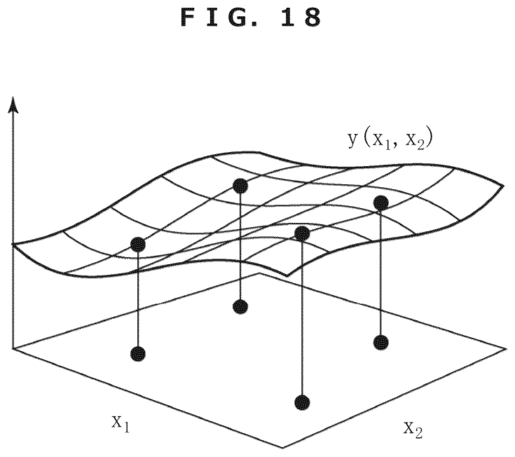

According to the fourth embodiment, the search space of the objective function y(x₁, . . . , x_{D}) including D parameters is defined by a D-dimensional space. For example, a two dimensional partial search space as the second dimension number is generated from a six dimensional search space as the first dimension number of the semiconductor element. FIG. 18 shows an example of a partial search space of the objective function y(x₁,x₂) defined in a two dimensional space. For example, a plurality of partial search spaces are generated so that each partial search space includes the current representative search point. The current representative search point is a design value that minimizes the objective function among the design values in the search history data. Compared to the first embodiment, a large number of parameters can be optimized in a short time by performing a low-dimensional search.

According to the parameter optimization method of at least one embodiment described above, it is possible to satisfy the end condition of the simulation earlier than the conventional method by determining the magnitude relationship between the calculation score and the discontinuation threshold.

In the specification of the present application, “perpendicular” and “parallel” include not only strictly perpendicular and strictly parallel but also, for example, variations in manufacturing processes, and may be substantially perpendicular and substantially parallel.

The embodiments of the present invention have been described above with reference to specific examples. However, the embodiments of the present invention are not limited to these specific examples. For example, one skilled in the art may similarly practice the invention by appropriately selecting specific configurations of components included in the parameter optimization system such as the Bayesian estimation unit, the calculation unit, the file generation unit, the determination unit, the extraction unit, the instruction generation unit, the input unit, the output unit, and the storage unit from known art; and such practice is within the scope of the invention to the extent that similar effects can be obtained.

Further, combinations of two or more elements of the specific examples within a technically possible range are also included in the scope of the invention as long as the combinations include the gist of the invention.

Moreover, all parameter optimization methods, parameter optimization systems, programs, and storage media practicable by an appropriate design modification by one skilled in the art based on the parameter optimization methods, parameter optimization systems, programs, and storage media described above as embodiments of the invention also are within the scope of the invention to the extent that the spirit of the invention is included.

In addition, within the scope of the idea of the present invention, those skilled in the art can conceive various modifications and corrections, and it is understood that the modifications and corrections also belong to the scope of the present invention.

While certain embodiments have been described, these embodiments have been presented by way of example only, and are not intended to limit the scope of the inventions. These embodiments can be implemented in various other forms, and various omissions, substitutions, and changes can be made without departing from the gist of the invention. These embodiments and their modifications are included within the scope and spirit of the invention, as well as within the scope of equivalents of the invention described in the claims.

What is claimed is:

1. A parameter optimization method, comprising:
generating a plurality of neighboring design value sets from a first representative design value set for a device;
acquiring from a simulator a first representative characteristic value set by inputting the first representative design value set to the simulator;
performing by the simulator a simulation related to a characteristic of the device;
acquiring a first neighboring characteristic value set output from the simulator in response to an input of a first neighboring design value set included in the plurality of neighboring design value sets;
calculating, in a calculation processor, a first calculation score calculated from the neighboring characteristic values included in the first neighboring characteristic value set;
determining, in the calculation processor, a magnitude relationship between the first calculation score and a discontinuation threshold;
inputting a second neighboring design value set included in the plurality of neighboring design value sets to the simulator if the first calculation score is greater than a discontinuation threshold;
calculating, in the calculation processor, a value of an objective function by inputting, to the objective function, a characteristic value included in the first representative characteristic value set and a characteristic value included in a neighboring characteristic value set output from the simulator in response to an input of one of neighboring design value sets included in the plurality of neighboring design value sets if the first calculation score is less than a discontinuation threshold;
calculating, in the calculation processor, an acquisition function by Bayes estimation from a proxy model of the objective function, the proxy model generated from a plurality of datasets stored in a storage;
generating a second representative design value set based on the acquisition function; and
when the second representative design value set satisfies a specified count, outputting the second representative design value set.

2. The parameter optimization method according to claim 1, further comprising:
determining, in the calculation processor, a magnitude relation between a value of the objective function and a target value;
determining, in the calculation processor, whether a number of times of calculation of the neighboring design value set reaches a predetermined expected number of times when the value of the objective function is larger than the target value; and
outputting as the second representative design value set a set of best design values when the value of the objective function is smaller than the target value.

3. The parameter optimization method according to claim 1, further comprising:
determining, in the calculation processor, a magnitude relationship between a value of the objective function and a target value;
determining, in the calculation processor, whether a number of times of calculation of the neighboring design value set reaches a prescribed expected number of times when the value of the objective function is smaller than the target value; and
outputting as the second representative design value set the set of best design values when the value of the objective function is larger than the target value.

4. The parameter optimization method according to claim 1, further comprising:
determining, in the calculation processor, whether there is the first representative design value set or the plurality of neighboring design value sets that have not been input to the simulator;
inputting a second neighboring design value set included in the plurality of neighboring design value sets to the simulator when there is the first representative design value set or the plurality of neighboring design value sets that have not been input to the simulator; and
calculating, in the calculation processor, a value of an objective function by inputting, to the objective function, the characteristic value included in the first representative characteristic value set and the characteristic value included in the neighboring characteristic value set output from the simulator by inputting one of the neighboring design value sets included in the plurality of neighboring design value sets when there is no first representative design value set or the plurality of neighboring design value sets that have not been input to the simulator, or when the calculation score is smaller than the discontinuation threshold in the determination of the magnitude relationship between the calculation score and the discontinuation threshold.

5. The parameter optimization method according to claim 1, further comprising:
determining, in the calculation processor, whether there is the first representative design value set or the plurality of neighboring design value sets that have not been input to the simulator;
inputting the second neighboring design value set included in the plurality of neighboring design value sets to the simulator when there is the first representative design value set or the plurality of neighboring design value sets that have not been input to the simulator;
calculating, in the calculation processor, a value of an objective function by inputting, to the objective function, the characteristic value included in the first representative characteristic value set and the characteristic value included in the neighboring characteristic value set output from the simulator by inputting one of the neighboring design value sets included in the plurality of neighboring design value sets when there is no first representative design value set or the plurality of neighboring design value sets that have not been input to the simulator, or when the calculation score is larger than the discontinuation threshold in the determination of the magnitude relationship between the calculation score and the discontinuation threshold.

6. The parameter optimization method according to claim 1, further comprising:
calculating, in the calculation processor, a first prediction score from each of the plurality of neighboring design value sets;
sorting, in the calculation processor, the plurality of neighboring design value sets in a descending order of the first prediction score; and
inputting a part of the neighboring design value set into the simulator in order of malignancy of the first prediction score.

7. The parameter optimization method according to claim 6, wherein
the first prediction score is a regression value of neighboring characteristic values or a combination of regression values of the neighboring characteristic values.

8. The parameter optimization method according to claim 6, further comprising:
acquiring a second representative characteristic value set output from the simulator in response to the input of the first representative design value set;
acquiring a second neighboring characteristic value set output from the simulator in response to an input of one of the plurality of neighboring design value sets;
calculating, in the calculation processor, a second calculation score of the neighboring characteristic value included in the second neighboring characteristic value set;
determining, in the calculation processor, whether to change an order of inputting the plurality of neighboring design value sets into the simulator, the plurality of neighboring design value sets being obtained by calculating a second prediction score from the plurality of neighboring design value sets and being sorted in order of malignancy of the first prediction score when the magnitude relation between the calculation score and the discontinuation threshold is a first determination result in the determination;
inputting a part of the neighboring design value set to a simulator in order of malignancy of the second prediction score when changing the input order; and
determining, in the calculation processor, whether there is the first representative design value set or the plurality of neighboring design value sets that have not been input to the simulator when the input order is not changed.

9. The parameter optimization method according to claim 1, further comprising:
calculating, in the calculation processor, the first calculation score of the neighboring characteristic value included in the first neighboring characteristic value set;
calculating, in the calculation processor, a value of an objective function by inputting a part of the first representative characteristic value set and a part of the first neighboring characteristic value set to the objective function in a case where a second determination result is obtained in the determination of the magnitude relationship between the calculation score and the discontinuation threshold;
outputting a best design value set from history data in a case where the second determination result is obtained in the determination of the magnitude relationship between the value of the objective function and a target value; and
discontinuing a search before all the representative design value sets and the neighboring design value sets are input to the simulator.

10. The parameter optimization method according to claim 1, further comprising:
generating a second dimensional partial search space, which is smaller than a first dimensional search space, from the first dimensional search space.

11. The parameter optimization method according to claim 1, further comprising:
generating, in the calculation processor, a plurality of neighboring design value sets from a first representative design value set for a device;
acquiring, at the calculation processor, a first representative characteristic value set output from a simulator by inputting the first representative design value set to the simulator;
performing, in the simulator, a simulation related to device characteristics;
acquiring, at the calculation processor, a first neighboring characteristic value set output from the simulator in response to an input of a first neighboring design value set included in the plurality of neighboring design value sets;
calculating, in the calculation processor, a first calculation score calculated from the neighboring characteristic values included in the first neighboring characteristic value set,
determining, in the calculation processor, a magnitude relationship between the first calculation score and a discontinuation threshold,
inputting, to the calculation processor, a second neighboring design value set included in the plurality of neighboring design value sets to the simulator in a case of a first determination result;
calculating, in the calculation processor, a value of an objective function by inputting, to the objective function, a characteristic value included in the first representative characteristic value set and a characteristic value included in a neighboring characteristic value set output from the simulator in response to an input of one of neighboring design value sets included in the plurality of neighboring design value sets in a case of a second determination result;
calculating, in the calculation processor, an acquisition function by the Bayes estimation from the proxy model of the objective function; and
generating, at the calculation processor, a second set of representative design values based on the acquisition function.

12. The parameter optimization method according to claim 1, further comprising:
generating, in the calculation processor, a plurality of neighboring design value sets from a first representative design value set for a device;
acquiring, at the calculation processor, a first representative characteristic value set output from the simulator by inputting the first representative design value set to the simulator;
executing, at the calculation processor, a simulation related to device characteristics;
acquiring, at the calculation processor, a first neighboring characteristic value set output from the simulator in response to an input of a first neighboring design value set included in the plurality of neighboring design value sets;
calculating, at the calculation processor, a first calculation score calculated from the neighboring characteristic values included in the first neighboring characteristic value set;
determining, at the calculation processor, a magnitude relationship between the first calculation score and a discontinuation threshold;
inputting to the simulator a second neighboring design value set included in the plurality of neighboring design value sets in a case of a first determination result;
calculating, at the calculation processor, a value of an objective function by inputting, to the objective function, a characteristic value included in the first representative characteristic value set and a characteristic value included in a neighboring characteristic value set output from the simulator in response to an input of one of neighboring design value sets included in the plurality of neighboring design value sets in a case of a second determination result;
calculating, at the calculation processor, an acquisition function by the Bayes estimation from the proxy model of the objective function; and
generating, at the calculation processor, a second set of representative design values based on the acquisition function.

13. The parameter optimization method according to claim 1, wherein
the determining the magnitude relationship between the value of the objective function and a target value includes:
determining whether a number of times of calculation of the neighboring design value set reaches a predetermined expected number of times when the value of the objective function is larger than the target value,
determining whether to change a design item group A when a number of times of calculation of the neighboring design value set reaches the predetermined expected number of times,
resetting the target value when the design item group A is changed, and
outputting a best design value set when the design item group A is not changed.

14. A parameter optimization method, for:
a design item set X including a design item group A, a design item group B, and a design item group C, wherein
the design item group A is a design item of search target,
the design item group B is a design item that take into account manufacturing variations, and
the design item group C is a design item obtained by excluding the design item group A and the design item group B from the design item set X,
a design value set x includes a design value group a corresponding to the design item group A, a design value group b corresponding to the design item group B, and a design value group c corresponding to the design item group C,
each design value group includes a plurality of design values,
the parameter optimization method comprising:
adjusting values of a design value group a by inputting the plurality of neighboring design value sets to a simulator;
generating, in a calculation processor, the neighboring design value set by changing a representative design value group of a first representative design value set to a neighboring design value group, and
generating, in the calculation processor, a second representative design value set by changing the value of the design value group a based on an acquisition function.

15. The parameter optimization method according to claim 14, wherein
the representative design value set includes the design value group a, the representative design value group, and the design value group c,
the neighboring design value set includes the design value group a, the neighboring design value group, and the design value group c, and
a representative characteristic value set is output when the representative design value set is input to the simulator, and
a neighboring characteristic value set is output when the neighboring design value set is input to the simulator.

16. The parameter optimization method according to claim 14, wherein
a certain design item is included in both the design item group a and the design item group b.

17. The parameter optimization method according to claim 15, wherein
a design value group is output from the simulator in response to an input of one of the representative design value group and the neighboring design value group,
the design value group includes at least one of the characteristic values selected from an on-resistance, a breakdown voltage when a gate voltage is 0 [V], a breakdown voltage when a gate voltage is applied, a switching charge, a gate accumulated charge, a gate-source accumulated charge, a gate-drain accumulated charge, an output charge, a threshold voltage, and a channel length.

18. The parameter optimization method according to claim 15, wherein
the plurality of neighboring design value sets are extracted at equal intervals at ends of a confidence interval of the representative design value set.

19. A parameter optimization method, comprising:
generating a plurality of neighboring design value sets from a first representative design value set for a device;
acquiring from a simulator a first representative characteristic value set by inputting the first representative design value set to the simulator;
performing in the simulator a simulation related to a characteristic of the device;
acquiring, at a calculation processor, a first neighboring characteristic value set output from the simulator in response to an input of a first neighboring design value set included in the plurality of neighboring design value sets;
calculating, in the calculation processor, a first calculation score calculated from the neighboring characteristic values included in the first neighboring characteristic value set; and
when the first calculation score satisfies a specified count, outputting a representative design value set.
